(19) United States
(12) Patent Application Publication
(10) Pub. No.: US 2026/0282937 A1
(43) Pub. Date: Sep. 17, 2026

(54) SEMICONDUCTOR PACKAGE AND METHOD FOR MANUFACTURING THE SAME

(71) Applicant: Samsung Electronics Co., Ltd., Suwon-si (KR)

(72) Inventors: Yeongseon Kim, Suwon-si (KR); Soohwan Lee, Suwon-si (KR); GyeongJae Jo, Suwon-si (KR)

(73) Assignee: Samsung Electronics Co., Ltd., Suwon-si (KR)

(21) Appl. No.: 19/378,498

(22) Filed: Nov. 4, 2025

(30) Foreign Application Priority Data
Mar. 13, 2025 (KR) 10-2025-0032966

(51) Int. Cl. H01L 23/00; H01L 23/544; H01L 25/065

(52) U.S. Cl. CPC H10W 46/00; H10W 90/00; H10W 46/301; H10W 72/923; H10W 72/926; H10W 72/932; H10W 72/936; H10W 72/9445; H10W 90/26; H10W 90/297; H10W 90/792

(57) ABSTRACT

A semiconductor package according to embodiments includes a first semiconductor die and a second semiconductor die on the first semiconductor die, the first semiconductor die comprising: a first die base; a first bonding dielectric layer on a back side of the first die base; a plurality of first key patterns penetrating the first bonding dielectric layer; and a plurality of second key patterns penetrating the first bonding dielectric layer, each second key pattern surrounding a corresponding first key pattern of the plurality of first key patterns, the second semiconductor die comprising: a second die base; a second bonding dielectric layer disposed on a front side of the second die base and bonded to the first bonding dielectric layer; a plurality of third key patterns penetrating the second bonding dielectric layer, each third key pattern bonding to a corresponding first key pattern of the plurality of first key patterns; and a plurality of fourth key patterns penetrating the second bonding dielectric layer, each fourth key pattern surrounding a corresponding third key pattern of the plurality of third key patterns and bonding to a corresponding second key pattern of the plurality of second key patterns, wherein: each of the plurality of first key patterns has a first width in a horizontal direction, each of the plurality of second key patterns has a second width in the horizontal direction, each of the plurality of third key patterns has a third width in the horizontal direction, each of the plurality of fourth key patterns has a fourth width in the horizontal direction, the first width is smaller than the third width, and the second width is larger than the fourth width.

### CROSS-REFERENCE TO RELATED APPLICATIONS

This present application claims priority to and the benefit under 35 U.S.C. § 119(a)-(d) of Korean Patent Application No. 10-2025-0032966, filed on Mar. 13, 2025, in the Korean Intellectual Property Office, the entire disclosure of which is incorporated herein by reference.

### BACKGROUND

The present disclosure relates to a semiconductor package and a method for manufacturing the semiconductor package.

The semiconductor industry, in response to demands for miniaturization and weight reduction in electronic devices, is pursuing the miniaturization, weight reduction, and thinning of semiconductor packages mounted in electronic devices while simultaneously enhancing speed, multifunctionality, and capacity. Accordingly, there is an increasing need for packaging technology capable of storing more data and transmitting data at higher speeds. As such packaging technology, a stacked semiconductor device formed by stacking a plurality of individual semiconductor chips (semiconductor dies) is being developed, such as High Bandwidth Memory (HBM).

The stacked semiconductor device is manufactured by the combination of same type or different type semiconductor chips, where it is important in this combination that the semiconductor chips are combined with a high density of I/Os. If the density of I/Os is increased so that the electrical signal connection density becomes similar to the wiring density in the front end process of semiconductors, then even if same type or different type semiconductor chips are combined in the back end process, a result similar to a single semiconductor chip made through the front end process can be achieved.

To manufacture semiconductor chips combined with high I/O density, a hybrid bonding process may be applied for combining semiconductor chips. Hybrid bonding bonds two devices by melting the same materials of two devices using the bonding properties of the same material. Here, hybrid refers to the bonding of two different types, for example, bonding two devices with bonding between metal-metal of the first type and bonding between dielectric-dielectric of the second type.

### SUMMARY

In a semiconductor package including semiconductor dies bonded by performing a hybrid bonding process, each semiconductor die may include key patterns having both the functions of a bonding key and an alignment key applied to hybrid bonding.

Each of key patterns of the lower semiconductor die and the corresponding key pattern of key patterns of the upper semiconductor die may be bonded to each other by hybrid bonding. To measure whether the bonded key patterns have been correctly bonded, each of the key patterns of the lower semiconductor die and the corresponding key pattern of key patterns of the upper semiconductor die have different line widths, and the key pattern with the smaller line width may be completely overlapped by the key pattern having the larger line width.

A method for manufacturing a semiconductor package may be provided, measuring the alignment accuracy between the key patterns of the lower semiconductor die and the key patterns of the upper semiconductor die before performing the hybrid bonding, performing the hybrid process between the lower semiconductor die and the upper semiconductor die, and measuring the bonding accuracy between the key patterns of the lower semiconductor die and the key patterns of the upper semiconductor die after the hybrid bonding is performed.

The semiconductor package according to the present disclosure comprises: a first semiconductor die and a second semiconductor die on the first semiconductor die, the first semiconductor die comprising: a first die base; a first bonding dielectric layer on a back side of the first die base; a plurality of first key patterns penetrating the first bonding dielectric layer; and a plurality of second key patterns penetrating the first bonding dielectric layer, each second key pattern surrounding a corresponding first key pattern of the plurality of first key patterns, the second semiconductor die comprising: a second die base; a second bonding dielectric layer disposed on a front side of the second die base and bonded to the first bonding dielectric layer; a plurality of third key patterns penetrating the second bonding dielectric layer, each third key pattern bonding to a corresponding first key pattern of the plurality of first key patterns; and a plurality of fourth key patterns penetrating the second bonding dielectric layer, each fourth key pattern surrounding a corresponding third key pattern of the plurality of third key patterns and bonding to a corresponding second key pattern of the plurality of second key patterns, wherein: each of the plurality of first key patterns has a first width in a horizontal direction, each of the plurality of second key patterns has a second width in the horizontal direction, each of the plurality of third key patterns has a third width in the horizontal direction, each of the plurality of fourth key patterns has a fourth width in the horizontal direction, the first width is smaller than the third width, and the second width is larger than the fourth width.

A semiconductor package according to the present disclosure comprises: a first semiconductor die comprising a first die base and a first bonding layer on a back side of the first die base; and a second semiconductor die comprising a second die base and a second bonding layer on a front side of the second die base, wherein the first bonding layer includes: a first dielectric layer; a plurality of first bonding pads penetrating the first dielectric layer; and a plurality of first key pattern groups penetrating the first dielectric layer, wherein each of the plurality of first key pattern groups includes a first inner key pattern and a first outer key pattern around the first inner key pattern, and the second bonding layer includes: a second dielectric layer bonded to the first dielectric layer; a plurality of second bonding pads penetrating the second dielectric layer, wherein each of the plurality of second bonding pads is bonded to a corresponding first bonding pad of the plurality of first bonding pads; and a plurality of second key pattern groups penetrating the second dielectric layer, wherein each of the plurality of second key pattern groups includes a second inner key pattern and a second outer key pattern around the second inner key pattern, and the second inner key pattern is bonded to the corresponding first inner key pattern, and the second outer key pattern is bonded to the corresponding first outer key pattern, wherein a width in a horizontal direction of the first inner key pattern is smaller than a width in the horizontal direction of the second inner key pattern, and a width in the horizontal direction of the first outer key pattern is larger than a width in the horizontal direction of the second outer key pattern.

A semiconductor package according to the present disclosure comprises: a semiconductor stack in which a plurality of semiconductor dies are sequentially stacked from the bottom, wherein each of the plurality of semiconductor dies comprises: a die base including a front side and a back side opposite the front side; a device layer on the front side; a wiring layer on the device layer; and at least one of a front side bonding layer on the wiring layer and a back side bonding layer on the back side, wherein each of the front side bonding layer and the back side bonding layer includes a dielectric layer and a plurality of key pattern groups penetrating the dielectric layer, and wherein each of the plurality of key pattern groups includes an inner key pattern and an outer key pattern surrounding the inner key pattern, wherein: the dielectric layer of back side bonding layer of each of the plurality of semiconductor dies is bonded to the dielectric layer of the front side bonding layer of an adjacent semiconductor die, the inner key pattern of back side bonding layer of each of the plurality of semiconductor dies is bonded to the inner key pattern of the front side bonding layer of an adjacent semiconductor die, the outer key pattern of back side bonding layer of each of the plurality of semiconductor dies is bonded to the outer key pattern of the front side bonding layer of an adjacent semiconductor die, the inner key pattern of back side bonding layer of each of the plurality of semiconductor dies has a first width in a horizontal direction, the outer key pattern of back side bonding layer of each of the plurality of semiconductor dies has a second width in the horizontal direction, the inner key pattern of front side bonding layer of each of the plurality of semiconductor dies has a third width in the horizontal direction, the outer key pattern of front side bonding layer of each of the plurality of semiconductor dies has a fourth width in the horizontal direction, the first width is less than the third width, and the second width is greater than the fourth width.

A method for manufacturing a semiconductor package according to the present disclosure includes aligning a second semiconductor die, which includes a plurality of third key patterns and a plurality of fourth key patterns, on a first semiconductor die, which includes a plurality of first key patterns and a plurality of second key patterns, wherein each second key pattern of the plurality of second key patterns surrounds a corresponding first key pattern of the plurality of first key patterns, and each fourth key pattern of the plurality of fourth key patterns surrounds a corresponding third key pattern of the plurality of third key patterns; photographing the plurality of first key patterns, the plurality of second key patterns, the plurality of third key patterns, and the plurality of fourth key patterns to measure the alignment accuracy between the first semiconductor die and the second semiconductor die; bonding the second semiconductor die to the first semiconductor die, wherein each first key pattern of the plurality of first key patterns is bonded to a corresponding third key pattern of the plurality of third key patterns, and each second key pattern of the plurality of second key patterns is bonded to a corresponding fourth key pattern of the plurality of fourth key patterns; and measuring the bonding accuracy between each first key pattern of the plurality of first key patterns and the corresponding third key pattern of the plurality of third key patterns, and between each second key pattern of the plurality of second key patterns and the corresponding fourth key pattern of the plurality of fourth key patterns.

In the method for manufacturing the semiconductor package, the photographing the plurality of first key patterns, the plurality of second key patterns, the plurality of third key patterns, and the plurality of fourth key patterns may be performed by a camera.

In the method for manufacturing the semiconductor package, the measuring the bonding accuracy may be performed by an infrared detection device.

in the method for manufacturing the semiconductor package, the step of measuring the bonding accuracy may include obtaining an image photographed by the infrared detection device.

In the method for manufacturing the semiconductor package, the image may include an image where each of the first key patterns of the plurality of first key patterns overlaps with a corresponding third key pattern of the plurality of third key patterns; and an image where each of the second key patterns of the plurality of second key patterns overlaps with a corresponding fourth key pattern of the plurality of fourth key patterns.

in the method for manufacturing the semiconductor package, the measuring the bonding accuracy may include determining whether the bonding is accurate by analyzing the image.

in the method for manufacturing the semiconductor package, the determining whether the bonding is accurate may include determining that the bonding is accurate if the image includes only the image of each second key pattern of the plurality of second key patterns and the image of each third key pattern of the plurality of third key patterns.

In the method for manufacturing the semiconductor package, the plurality of first key patterns each have a first width in a horizontal direction, the plurality of second key patterns each having a second width in the horizontal direction, the plurality of third key patterns each having a third width in the horizontal direction, and the plurality of fourth key patterns each having a fourth width in the horizontal direction, wherein the first width is smaller than the third width, and the second width may be larger than the fourth width.

In the method for manufacturing the semiconductor package, the plurality of first key patterns and the plurality of third key patterns each in a plane may include a closed-loop shape of a ring, a polygonal frame, or a cross-shaped; an elongated shape; or a circular arc shape.

In the method for manufacturing the semiconductor package, the plurality of second key patterns and the plurality of fourth key patterns each in a plane may include a closed-loop shape of a ring, a polygonal frame, or a cross-shaped; an elongated shape; or a circular arc shape.

In the method for manufacturing the semiconductor package, each of the plurality of first key patterns may be completely overlapped in a vertical direction with a corresponding third key pattern of the plurality of third key patterns.

In the method for manufacturing the semiconductor package, each of the plurality of fourth key patterns may be completely overlapped in the vertical direction with the corresponding second key pattern of the plurality of second key patterns.

In the method for manufacturing the semiconductor package, an outline of the planar shape of each of the plurality of first key patterns extends conformally along an outline of the planar shape of a corresponding third key pattern of the plurality of third key patterns.

In the method for manufacturing the semiconductor package, an outline of planar shape of each of the plurality of fourth key patterns extends conformally along an outline of the planar shape of the corresponding second key pattern of the plurality of second key patterns.

A method for manufacturing a semiconductor package according to the present disclosure may include aligning a second semiconductor die having a second dielectric layer and a plurality of second key pattern groups penetrating the second dielectric layer on a first semiconductor die including a first dielectric layer and a plurality of first key pattern groups penetrating the first dielectric layer, wherein each of the plurality of first key pattern groups includes a first inner key pattern and a first outer key pattern surrounding the first inner key pattern, and each of the plurality of second key pattern groups includes a second inner key pattern and a second outer key pattern surrounding the second inner key pattern; photographing each of the plurality of first key pattern groups and the plurality of second key pattern groups to measure the alignment accuracy of the first semiconductor die and the second semiconductor die; bonding the second dielectric layer to the first dielectric layer and bonding each of the plurality of second key pattern groups to a corresponding first key pattern group of the plurality of first key pattern groups; and measuring the bonding accuracy between the corresponding first key pattern group of plurality of first key pattern groups and each of the plurality of second key pattern groups.

In the method for manufacturing the semiconductor package, the measuring the alignment accuracy of the first semiconductor die and the second semiconductor die may be performed by comparing the first image photographed for the plurality of first key pattern groups with the second image photographed for the plurality of second key pattern groups.

In the method for manufacturing the semiconductor package, a width in a horizontal direction of the first inner key pattern is smaller than a width in the horizontal direction of the second inner key pattern, and a width in the horizontal direction of the first outer key pattern may be greater than a width in the horizontal direction of the second outer key pattern.

In the method for manufacturing the semiconductor package, the bonding each of the plurality of second key pattern groups to a corresponding first key pattern group of the plurality of first key pattern groups may include bonding a second inner key pattern of each of the plurality of second key pattern groups to a corresponding first inner key pattern of each of the plurality of first key pattern groups, and bonding a second outer key pattern of each of the plurality of second key pattern groups to a corresponding first outer key pattern of each of the plurality of first key pattern groups.

In the method for manufacturing the semiconductor package, the measuring the bonding accuracy may include measuring the bonding accuracy of a first inner key pattern of each of the plurality of first key pattern groups and a corresponding second inner key pattern of each of the plurality of second key pattern groups, and measuring the bonding accuracy of a first outer key pattern of each of the plurality of first key pattern groups and a corresponding second outer key pattern of each of the plurality of second key pattern groups.

(20) A method for manufacturing a semiconductor package according to the present disclosure includes aligning a second wafer including a plurality of second semiconductor dies on a first wafer including a plurality of first semiconductor dies, wherein each of the plurality of first semiconductor dies has a first die base; a first dielectric layer on the front side of the first die base; a plurality of first bonding pads penetrating the first dielectric layer; and a plurality of first key pattern groups penetrating the first dielectric layer, wherein each of the plurality of first key pattern groups includes a first inner key pattern and a first outer key pattern surrounding the first inner key pattern, and each of the plurality of second semiconductor dies has a second die base; a second dielectric layer on the back surface of the second die base; a plurality of second bonding pads penetrating the second dielectric layer; and a plurality of second key pattern groups penetrating the second dielectric layer, wherein each of the plurality of second key pattern groups includes a second inner key pattern and a second outer key pattern surrounding the second inner key pattern; photographing each of the plurality of first key pattern groups and the plurality of second key pattern groups to measure the alignment accuracy of the first wafer and the second wafer; bonding the second dielectric layer to the first dielectric layer, bonding each second bonding pad of the plurality of second bonding pads to a corresponding first bonding pad of the plurality of first bonding pads, bonding each second key pattern group of the plurality of second key pattern groups to a corresponding first key pattern group of the plurality of first key pattern groups; and measuring the bonding accuracy between the corresponding first key pattern group of the plurality of first key pattern groups and each of the plurality of second key pattern groups.

A single key pattern may perform both the bonding key function and the alignment key function, thereby reducing the area occupied by key patterns on a semiconductor die, and thus, the size of the semiconductor die may be decreased.

A hybrid process is applied to each of the key patterns of the lower semiconductor die and the corresponding key pattern of the key patterns of the upper semiconductor die, and each of the key patterns of the lower semiconductor die is bonded to the corresponding key pattern of the key patterns of the upper semiconductor die, so the bonding quality between the semiconductor dies may be improved.

A line width of each of the key patterns of of the lower semiconductor die and a line width of a corresponding key pattern of each of key patterns of the upper semiconductor die are designed differently. The key pattern with a smaller line width completely overlaps the key pattern with a larger line width by bonding each of the key patterns of the lower semiconductor die to the corresponding key pattern of key patterns of the upper semiconductor die. Then, measurements are performed on the overlapped and bonded key patterns to measure the bonding accuracy between the semiconductor dies. Accordingly, the metal ratio within the bonding layer of each semiconductor die may be increased, and the spacing between the key patterns may be reduced. As a result, the topography of the bonding surface can be improved, preventing voids from forming on the bonding surface or delamination from occurring between bonding surfaces.

### BRIEF DESCRIPTION OF THE DRAWINGS

FIG. 1 is a cross-sectional view showing a semiconductor package according to embodiments.

FIG. 2 is a plan view illustrating the bonding surface of the first semiconductor die of FIG. 1.

FIG. 3 is a plan view showing the bonding surface of the second semiconductor die of FIG. 1.

FIG. 4 is a plan view illustrating the first key pattern group of FIG. 2 and the second key pattern group of FIG. 3.

FIG. 5 is a cross-sectional view, which is an enlarged illustration of area A of FIG. 1, and a plan view showing the first key pattern group and the second key pattern group overlapped with each other in area A.

FIG. 6 is a plan view showing the first key pattern group, the second key pattern group, and the first key pattern group and the second key pattern group overlapped with each other, according to embodiments.

FIG. 7 is a plan view illustrating a first key pattern group, a second key pattern group, and the first key pattern group and the second key pattern group overlapped with each other, according to embodiments.

FIG. 8 is a plan view illustrating the first key pattern group, the second key pattern group, and the first and second key pattern groups overlapped with each other, according to embodiments.

FIG. 9 is a plan view illustrating the first key pattern group, the second key pattern group, and the first key pattern group and the second key pattern group overlapped with each other, according to embodiments.

FIG. 10 is a plan view illustrating the first key pattern group, second key pattern group, and the first key pattern group and the second key pattern group overlapped with each other, according to embodiments.

FIG. 11 to FIG. 18 are cross-sectional views for explaining a method for manufacturing the semiconductor package of embodiments of FIG. 1.

FIG. 19 is a cross-sectional view illustrating a semiconductor package according to embodiments.

FIG. 20 is a plan view showing the bonding surface of the base die of FIG. 19.

FIG. 21 is a plan view illustrating the front side bonding surface and the back side bonding surface of the semiconductor die of FIG. 19.

FIG. 22 to FIG. 31 are cross-sectional views for explaining a method for manufacturing a semiconductor package of embodiments in FIG. 19.

### DETAILED DESCRIPTION

Hereinafter, with reference to accompanying drawings, various embodiments of the present disclosure will be described in detail so that a person of an ordinary skill can easily implement the present disclosure. The present disclosure may be implemented in many different forms and is not limited to the embodiments described herein.

In order to clearly explain the present disclosure, parts that are not relevant to the description are omitted, and identical or similar components are assigned the same reference numerals throughout the specification.

In addition, the size and thickness of each component shown in the drawings are shown arbitrarily for convenience of explanation, so the present disclosure is not necessarily limited to what is shown.

Throughout the specification, when a part is said to be “connected” to another part, this includes not only “directly connected” but also “indirectly connected” through another member. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, being “on” or “above” a reference element means being positioned on or below the reference element, and does not necessarily mean being positioned “above” or “on” in a direction opposite to gravity.

In addition, throughout the specification, when referring to “a plane view”, it means that the target portion is viewed from above, and when referring to “a cross-section view”, it means that a cross section of the target portion cut vertically is viewed from a side.

In hybrid bonding, bonding between metal-to-metal is conducted through a process of bonding each of the bonding pads formed on the bonding surface of one semiconductor chip to a corresponding bonding pad of bonding pads formed on the bonding surface of another semiconductor chip. Semiconductor chips may exchange electrical signals with each other through routing paths formed by such metal-to-metal bonding. Hence, the bonding pads formed on the bonding surface of each semiconductor chip must be precisely aligned and bonded to each other. For this purpose, each semiconductor chip may include bonding keys to verify the accurate alignment of bonding pads before performing hybrid bonding, and alignment keys to measure bonding accuracy after performing hybrid bonding.

The bonding key may be measured before performing hybrid bonding, allowing for direct imaging, whereas the alignment key may be measured after performing hybrid bonding, requiring an imaging method that penetrates arbitrary structures. Due to this difference in measurement methods, the bonding key and alignment key are generally formed as separate structures, and the individually formed bonding keys and alignment keys may occupy relatively large areas on the semiconductor chip, thus causing an increase in the size of the semiconductor chip.

Additionally, the alignment keys of the semiconductor chips are designed such that the patterns of the alignment key of the upper semiconductor chip and the patterns of the alignment key of the lower semiconductor chip do not overlap for measurement. In this case, in a stacked semiconductor device where hybrid bonding is performed, an interface is formed where the dielectric and metal come into contact, and at such an interface, the dielectric and metal do not adhere to each other, which may result in voids forming on the bonding surface or delamination occurring between bonding surfaces.

Additionally, by the alignment key patterns of the upper semiconductor chip and the alignment key patterns of the lower semiconductor chip, designed not to overlap each other, the patterns of the alignment keys of each semiconductor chip may be arranged having increased spacing. Furthermore, the patterns of the alignment keys may include eroded (or dished) portions by a Chemical Mechanical Polishing (CMP) process performed on the bonding surface of each semiconductor chip. These structural features may make the spacing of the patterns of alignment keys, including the eroded portions, irregular, which may result in the deterioration of the topography of the bonding surface, and voids may be formed on the bonding surface, or delamination may occur between the bonding surfaces.

Hereinafter, a method for manufacturing a semiconductor package 10 and 20, and the semiconductor package 10 and 20, will be described with reference to the drawings.

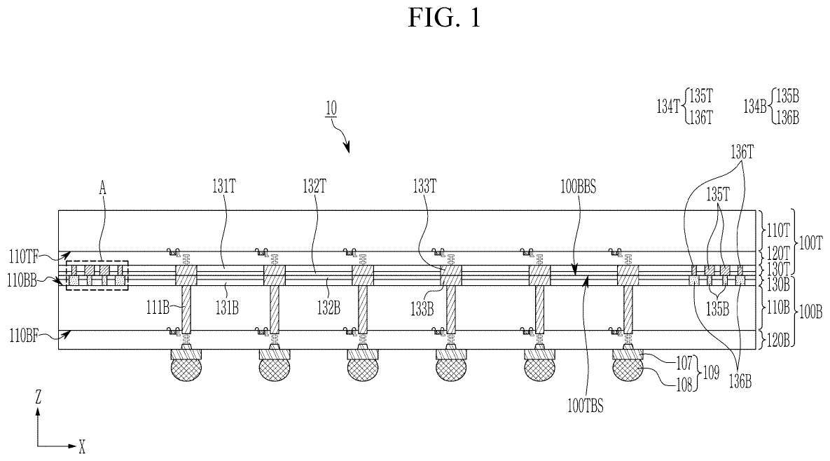

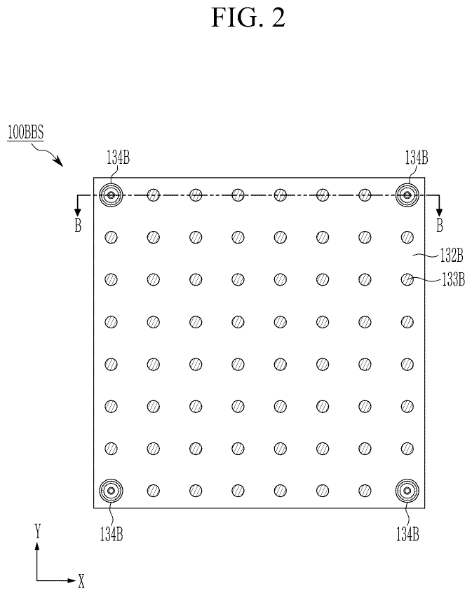

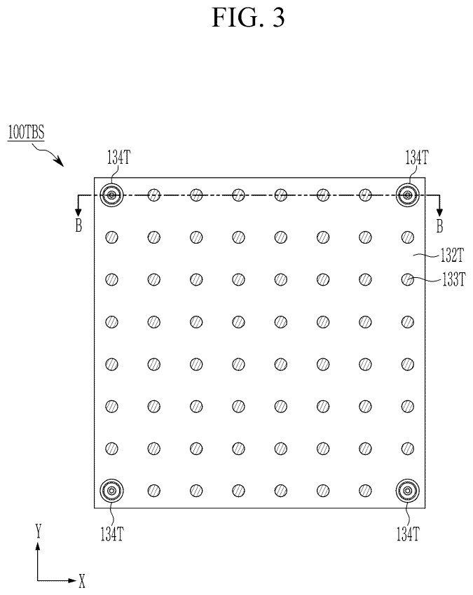

FIG. 1 is a cross-sectional view illustrating a semiconductor package 10 of embodiments. FIG. 1 is a cross-sectional view showing the first semiconductor die 100B of FIG. 2 and the second semiconductor die 100T of FIG. 3 cut along line B-B.

Referring to FIG. 1, the semiconductor package (semiconductor die stack) 10 may include a first semiconductor die (lower semiconductor die) 100B, a second semiconductor die (upper semiconductor die) 100T, and a bump structure 109. In embodiments, the semiconductor package 10 may include a System In Package (SIP). The semiconductor package 10 is implemented as a semiconductor package with two or more semiconductor dies, which may operate like a single chip. In embodiments, the semiconductor package 10 may include a 3D Integrated Circuit (3DIC). In embodiments, the semiconductor package 10 may include a System on Chip (SoC) or an Application Processor (AP). In embodiments, the semiconductor package 10 may be a semiconductor package manufactured based on Fan Out Wafer Level Package (FOWLP) or Fan Out Panel Level Package (FOPLP) technology.

The first semiconductor die 100B and the second semiconductor die 100T may constitute a semiconductor stack (semiconductor die stack) bonded to each other by hybrid bonding. The first semiconductor die 100B and the second semiconductor die 100T may be same type dies or different type dies. In FIG. 1, a semiconductor package 10 including the first semiconductor die 100B and the second semiconductor die 100T is disclosed, but this is not limited thereto, and the semiconductor package 10 may include three or more semiconductor dies.

When the first semiconductor die 100B and the second semiconductor die 100T are same dies, the first semiconductor die 100B and the second semiconductor die 100T may include the same configuration. In embodiments, the first semiconductor die 100B and the second semiconductor die 100T may include memory dies. In embodiments, the first semiconductor die 100B and the second semiconductor die 100T may include Dynamic Random-Access Memory (DRAM).

When the first semiconductor die 100B and the second semiconductor die 100T are different dies, the first semiconductor die 100B and the second semiconductor die 100T may include different configurations. In embodiments, the first semiconductor die 100B includes a logic die, and the second semiconductor die 100T may include a memory die. In embodiments, the first semiconductor die 100B includes a system on chip (SoC) or an application processor (AP), and the second semiconductor die 100T may include DRAM. In embodiments, the first semiconductor die 100B and the second semiconductor die 100T may each include a chiplet formed by dividing a logic die.

The first semiconductor die 100B may include a first die base 110B, through silicon vias (TSV) 111B, a first front side structure 120B, and a first bonding layer (first bonding structure) 130B. The first die base 110B may include a front side 110BF and a back side 110BB, which is opposite the front side 110BF. The first die base 110B may be a die formed from a wafer. In embodiments, the first die base 110B may include silicon or other semiconductor materials.

The through silicon vias 111B may extend from the wiring layer of the first front side structure 120B through the first die base 110B to the back side 110BB of the first die base 110B. A first end of each of the through silicon vias (TSV) 111B is connected to a corresponding first bonding pad 133B of the first bonding pads 133B of the first bonding layer 130B, and a second end of each of the through silicon vias (TSV) 111B may be connected to the wiring lines of the wiring layer. The second end may be the opposite end of the first end. In embodiments, the through silicon vias (TSV) 111B may include at least one of tungsten, aluminum, copper, and their alloys. A barrier layer may be formed around each of the through silicon vias (TSV) 111B. The barrier layer may prevent the silicon of the first die base 110B or the dielectric of the first front side structure 120B from contacting the through silicon via 111B. In embodiments, the barrier layer may include at least one of titanium, tantalum, titanium nitride, tantalum nitride, and their alloys.

The first front side structure 120B may be disposed on the front side 110BF of the first die base 110B. The first front side structure 120B may include a device layer and a wiring layer. The device layer may be disposed on the front side 110BF of the first die base 110B. The device layer may include an integrated circuit structure having integrated circuit regions. In embodiments, the integrated circuit structure may include at least one of active devices and passive devices. In embodiments, the integrated circuit structure may include a gate structure, a source region, and a drain region. In embodiments, the integrated circuit structure may include at least one of a transistor, a diode, a capacitor, an inductor, and a resistor. The wiring layer may be disposed on the device layer. The wiring layer may include signal wiring lines, power wiring lines, contact plugs, and an inter metal dielectric (IMD).

The first bonding layer 130B may be disposed on the back side 110BB of the first die base 110B. The first bonding layer 130B may include a first lower dielectric layer 131B, a first bonding dielectric layer (first dielectric layer) 132B, first bonding pads 133B, and first key pattern groups 134B.

The first lower dielectric layer 131B may be disposed on the back side 110BB of the first die base 110B. The first lower dielectric layer 131B may be disposed between the first die base 110B and the first bonding dielectric layer 132B. The first lower dielectric layer 131B may surround the first bonding pads 133B, and the first key pattern groups 134B. In embodiments, the first lower dielectric layer 131B may include silicon oxide, TEOS-formed oxide, or combinations thereof. In embodiments, the first lower dielectric layer 131B may have a thickness in the vertical direction (Z direction) in the range of about 0.1 μm to about 7 μm.

The first bonding dielectric layer 132B may be disposed on the first lower dielectric layer 131B. The first bonding dielectric layer 132B may be disposed between the first lower dielectric layer 131B and the second bonding dielectric layer 132T of the second semiconductor die 100T. The first bonding dielectric layer 132B may be bonded to the second bonding dielectric layer 132T of the second semiconductor die 100T by performing dielectric-to-dielectric hybrid bonding. The first bonding dielectric layer 132B may surround the first bonding pads 133B, and the first key pattern groups 134B. In embodiments, the first bonding dielectric layer 132B may include a silicon compound. In embodiments, the first bonding dielectric layer 132B may include silicon oxide or silicon nitride. In embodiments, the first bonding dielectric layer 132B may include SiO₂, SiN, or SiCN. In embodiments, the first bonding dielectric layer 132B may have a thickness in the range of about 0.05 μm to about 1 μm in the vertical direction (Z direction).

The first bonding pads 133B may penetrate the first lower dielectric layer 131B and the first bonding dielectric layer 132B. Each of the first bonding pads 133B may be disposed between a corresponding through silicon via (TSV) 111B of the through silicon vias (TSV) 111B and a corresponding second bonding pad 133T of the second bonding pads 133T of a second semiconductor die 100T. Each of the first bonding pads 133B may electrically connect a corresponding through silicon via (TSV) 111B of the through silicon vias (TSV) 111B to a corresponding second bonding pad 133T of the second bonding pads 133T of the second semiconductor die 100T. Each of the first bonding pads 133B may be bonded to a corresponding second bonding pad 133T of the second bonding pads 133T of the second semiconductor die 100T through metal-metal hybrid bonding. This metal-metal hybrid bonding may achieve electrical connection between the first semiconductor die 100B and the second semiconductor die 100T. Each bonding surface of the first bonding pads 133B may be coplanar with the bonding surface of the first bonding dielectric layer 132B. The sides of the first bonding pads 133B may be surrounded by the first lower dielectric layer 131B and the first bonding dielectric layer 132B. In embodiments, each of the first bonding pads 133B may have a width in a range of about 0.01 μm to about 30 μm in the horizontal direction (X and Y directions). In embodiments, each of the first bonding pads 133B may have a thickness in a range of about 0.1 μm to about 8 μm in the vertical direction (Z direction). In embodiments, the first bonding pads 133B may include copper or a copper alloy.

The first key pattern groups 134B may penetrate the first lower dielectric layer 131B and the first bonding dielectric layer 132B. The first key pattern groups 134B may be dummy patterns. The first key pattern groups 134B may be electrically isolated from other configurations within the semiconductor package 10. Each of the first key pattern groups 134B may include a first inner key pattern (first key pattern) 135B and a first outer key pattern (second key pattern) 136B surrounding the first inner key pattern 135B. The first key pattern groups 134B may include the same material as the first bonding pads 133B.

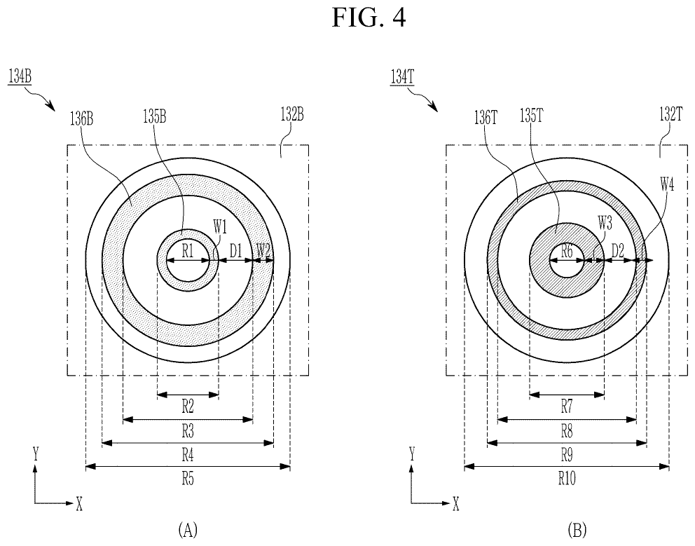

The first inner key patterns 135B may penetrate the first lower dielectric layer 131B and the first bonding dielectric layer 132B. The first inner key patterns 135B may be dummy patterns. The first inner key patterns 135B may be electrically isolated from other configurations within the semiconductor package 10. Each of the first inner key patterns 135B may be surrounded by a corresponding first outer key pattern 136B of the first outer key patterns 136B in the horizontal direction (X direction and Y direction; refer to FIG. 4). Each of the first inner key patterns 135B may be spaced apart from a corresponding first outer key pattern 136B of the first outer key patterns 136B in the horizontal direction (X direction and Y direction; refer to FIG. 4). Each of the first inner key patterns 135B may be bonded to a corresponding second inner key pattern 135T of the second inner key patterns 135T of the second semiconductor die 100T by performing metal-metal hybrid bonding. Each bonding surface of the first inner key patterns 135B may be coplanar with the bonding surface of the first bonding dielectric layer 132B. The sides of each of the first inner key patterns 135B may be surrounded by the first lower dielectric layer 131B and the first bonding dielectric layer 132B. In embodiments, each of the first inner key patterns 135B may have a thickness in the range of about 0.1 μm to about 8 μm in the vertical direction (Z direction). In embodiments, the first inner key patterns 135B may include copper or a copper alloy.

The first outer key patterns 136B may penetrate the first lower dielectric layer 131B and the first bonding dielectric layer 132B. The first outer key patterns 136B may be dummy patterns. The first outer key patterns 136B may be electrically isolated from other configurations within the semiconductor package 10. Each of the first outer key patterns 136B may surround a corresponding first inner key pattern 135B of the first inner key patterns 135B in a horizontal direction (X direction and Y direction; refer to FIG. 4). Each of the first outer key patterns 136B may be spaced apart from a corresponding first inner key pattern 135B of the first inner key patterns 135B in the horizontal direction (X direction and Y direction; refer to FIG. 4). Each of the first outer key patterns 136B may be bonded to a corresponding second outer key pattern 136T of the second outer key patterns 136T of the second semiconductor die 100T by performing a metal-metal hybrid bonding. Bonding surface of each of the first outer key patterns 136B may be coplanar with the bonding surface of the first bonding dielectric layer 132B. The sides of each of the first outer key patterns 136B may be surrounded by the first lower dielectric layer 131B and the first bonding dielectric layer 132B. In embodiments, each of the first outer key patterns 136B may have a thickness in the range of about 0.1 μm to about 8 μm in the vertical direction (Z direction). In embodiments, the first outer key patterns 136B may include copper or a copper alloy.

The second semiconductor die 100T may be disposed on the first semiconductor die 100B. The second semiconductor die 100T may include a second die base 110T, a second front side structure 120T, and a second bonding layer (second bonding structure) 130T. The second die base 110T may be a die formed from a wafer. In embodiments, the second die base 110T may include silicon or other semiconductor material.

The second front side structure 120T may be disposed on the front side 110TF of the second die base 110T. The second front side structure 120T may include a device layer and a wiring layer. The device layer may be disposed on the front side 110TF of the second die base 110T. The device layer may include an integrated circuit structure having integrated circuit regions. In embodiments, the integrated circuit structure may include at least one of an active device and a passive device. In embodiments, the integrated circuit structure may include a gate structure, a source region, and a drain region. In embodiments, the integrated circuit structure may include at least one of a transistor, a diode, a capacitor, an inductor, and a resistor. The wiring layer may be disposed on the device layer. The wiring layer may include wiring lines for signals, wiring lines for power, contact plugs, and an inter metal dielectric (IMD).

The second bonding layer 130T may be disposed on the second front side structure 120T of the second die base 110T. The second bonding layer 130T may include a second lower dielectric layer 131T, a second bonding dielectric layer (second dielectric layer) 132T, second bonding pads 133T, and second key pattern groups 134T.

The second lower dielectric layer 131T may be disposed on the second front side structure 120T of the second die base 110T. The second lower dielectric layer 131T may be disposed between the second die base 110T and the second bonding dielectric layer 132T. The second lower dielectric layer 131T may surround the second bonding pads 133T and the second key pattern groups 134T. In embodiments, the second lower dielectric layer 131T may include silicon oxide, TEOS-formed oxide, or combinations thereof. In embodiments, the second lower dielectric layer 131T may have a thickness in the range of about 0.1 μm to about 7 μm in the vertical direction (Z direction).

The second bonding dielectric layer 132T may be disposed on the second lower dielectric layer 131T. The second bonding dielectric layer 132T may be disposed between the second lower dielectric layer 131T and the first bonding dielectric layer 132B of the first semiconductor die 100B. The second bonding dielectric layer 132T may be bonded to the first bonding dielectric layer 132B of the first semiconductor die 100B by performing dielectric-dielectric hybrid bonding. The second bonding dielectric layer 132T may surround the second bonding pads 133T and the second key pattern groups 134T. In embodiments, the second bonding dielectric layer 132T may include a silicon compound. In embodiments, the second bonding dielectric layer 132T may include silicon oxide or silicon nitride. In embodiments, the second bonding dielectric layer 132T may include SiO₂, SiN, or SiCN. In embodiments, the second bonding dielectric layer 132T may have a thickness in a range from about 0.05 μm to about 1 μm in the vertical direction (Z direction).

The second bonding pads 133T may penetrate the second lower dielectric layer 131T and the second bonding dielectric layer 132T. Each of the second bonding pads 133T may be disposed between a wiring line of the wiring layer of the second front side structure 120T and the corresponding first bonding pad 133B of the first bonding pads 133B of the first semiconductor die 100B. Each of the second bonding pads 133T may electrically connect a wiring line of the wiring layer of the second front side structure 120T to the corresponding first bonding pad 133B of the first bonding pads 133B of the first semiconductor die 100B. Each of the second bonding pads 133T may be bonded to the corresponding first bonding pad 133B of the first bonding pads 133B of the first semiconductor die 100B by performing a metal-metal hybrid bonding. The bonding surface of each of the second bonding pads 133T may be coplanar with the bonding surface of the second bonding dielectric layer 132T. The sides of the second bonding pads 133T may be surrounded by the second lower dielectric layer 131T and the second bonding dielectric layer 132T. In embodiments, each of the second bonding pads 133T may have a width in the range of about 0.01 μm to about 30 μm in the horizontal direction (X direction and Y direction). In embodiments, each of the second bonding pads 133T may have a thickness in the range of about 0.1 μm to about 8 μm in the vertical direction (Z direction). In embodiments, the second bonding pads 133T may include copper or a copper alloy.

The second key pattern groups 134T may penetrate the second lower dielectric layer 131T and the second bonding dielectric layer 132T. The second key pattern groups 134T may be dummy patterns. The second key pattern groups 134T may be electrically isolated from other configurations within the semiconductor package 10. Each of the second key pattern groups 134T may include a second inner key pattern (third key pattern; 135T) and a second outer key pattern (fourth key pattern; 136T) around the second inner key pattern 135T. The second key pattern groups 134T may include the same material as the second bonding pads 133T.

The second inner key patterns 135T may penetrate the second lower dielectric layer 131T and the second bonding dielectric layer 132T. The second inner key patterns 135T may be dummy patterns. The second inner key patterns 135T may be electrically isolated from other configurations within the semiconductor package 10. Each of the second inner key patterns 135T may be surrounded by a corresponding second outer key pattern 136T of the second outer key patterns 136T in the horizontal direction (X direction and Y direction; refer to FIG. 4). Each of the second inner key patterns 135T may be spaced apart from a corresponding second outer key pattern 136T of the second outer key patterns 136T in the horizontal direction (X direction and Y direction; refer to FIG. 4). Each of the second inner key patterns 135T may be bonded to a corresponding first inner key pattern 135B of the first inner key patterns 135B of the first semiconductor die 100B by performing metal-metal hybrid bonding. The bonding surface of each of the second inner key patterns 135T may be coplanar with the bonding surface of the second bonding dielectric layer 132T. The sides of each of the second inner key patterns 135T may be surrounded by the second lower dielectric layer 131T and the second bonding dielectric layer 132T. In embodiments, each of the second inner key patterns 135T may have a thickness in the range of about 0.1 μm to about 8 μm in the vertical direction (Z direction). In embodiments, the second inner key patterns 135T may include copper or a copper alloy.

The second outer key patterns 136T may penetrate the second lower dielectric layer 131T and the second bonding dielectric layer 132T. The second outer key patterns 136T may be a dummy pattern. The second outer key patterns 136T may be electrically isolated from other configurations within the semiconductor package 10. Each of the second outer key patterns 136T may surround a corresponding second inner key pattern 135T of the second inner key patterns 135T in a horizontal direction (X direction and Y direction; refer to FIG. 4). Each of the second outer key patterns 136T may be spaced apart from a corresponding second inner key pattern 135T of the second inner key patterns 135T in the horizontal direction (X direction and Y direction; refer to FIG. 4). Each of the second outer key patterns 136T may be bonded to a corresponding first outer key pattern 136B of the first outer key patterns 136B of the first semiconductor die 100B by performing metal-metal hybrid bonding. The bonding surface of each of the second outer key patterns 136T may be coplanar with the bonding surface of the second bonding dielectric layer 132T. The sides of each of the second outer key patterns 136T may be surrounded by the second lower dielectric layer 131T and the second bonding dielectric layer 132T. In embodiments, each of the second outer key patterns 136T may have a thickness in the range of about 0.1 μm to about 8 μm in a vertical direction (Z direction). In embodiments, the second outer key patterns 136T may include copper or a copper alloy.

The bump structures 109 may be disposed between the first semiconductor die 100B and an external device. Each of the bump structures 109 is disposed on a corresponding wiring of wirings of the first front side structure 120B of the first semiconductor die 100B, and may electrically connect the corresponding wiring of wirings of the first front side structure 120B to the external device. Each of the bump structures 109 may include a bump pillar 107 and a solder ball 108. In embodiments, the bump structures 109 may include micro bumps. The bump pillar 107 may be disposed between a corresponding wiring of wirings of the first front side structure 120B and the solder ball 208. In embodiments, the bump pillar 107 may be formed of a copper alloy including silver, chromium, nickel, tin, gold, and combinations thereof, or copper. In embodiments, the solder ball 108 may include at least one of tin, silver, lead, nickel, copper, and their alloys.

FIG. 2 is a plan view showing the bonding surface (100BBS) of the first semiconductor die 100B of FIG. 1.

Referring to FIG. 2, each of the first key pattern groups 134B may be disposed at a corner of the first die base 110B (or, the bonding surface (100BBS)) of the first semiconductor die 100B. The first key pattern groups 134B function as bonding keys and alignment keys together with the second key pattern groups 134T, and the first key pattern groups 134B may be disposed at the edge on the bonding surface (100BBS) of the first semiconductor die 100B in comparison to the first bonding pads 133B.

FIG. 3 is a plan view showing the bonding surface 100TBS of the second semiconductor die 100T of FIG. 1.

Referring to FIG. 3, each of the second key pattern groups 134T may be disposed on one corner of the second die base 110T (or the bonding surface 100TBS) of the second semiconductor die 100T. The second key pattern groups 134T function as bonding keys and alignment keys together with the first key pattern groups 134B, and the second key pattern groups 134T may be disposed at the outermost edge on the bonding surface 100TBS of the second semiconductor die 100T compared to the second bonding pads 133T.

FIG. 4 is a plan view showing the first key pattern group 134B of FIG. 2 and the second key pattern group 134T of FIG. 3.

Referring to (A) of FIG. 4, the first key pattern group 134B may include the first inner key pattern 135B and the first outer key pattern 136B. The first outer key pattern 136B may surround the first inner key pattern 135B in the horizontal direction (X direction and Y direction). The first outer key pattern 136B may be spaced apart from the first inner key pattern 135B in the horizontal direction (X direction and Y direction) by the first bonding dielectric layer 132B. In embodiments, the first key pattern group 134B may have a size R5 in the range of about 14 μm to about 42 μm in the horizontal direction (X direction and Y direction). The first inner key pattern 135B may extend with a first width W1. The first outer key pattern 136B may extend with a second width W2. The first width W1 may be smaller than the second width W2.

In embodiments, the first inner key pattern 135B may have a closed-loop shape of a ring on a plane (bonding surface 100BBS). In embodiments, the first inner key pattern 135B may extend with a first width W1 in the range of about 1 μm to about 3 μm in the horizontal direction (X direction and Y direction). In embodiments, the first inner key pattern 135B may have an inside diameter R1 in the range of about 3 μm to about 9 μm in the horizontal direction (X direction and Y direction). In embodiments, the first inner key pattern 135B may have an outside diameter R2 in the range of about 5 μm to about 15 μm in the horizontal direction (X direction and Y direction).

In embodiments, a first outer key pattern 136B may have a closed-loop shape of a ring on a plane (bonding surface 100BBS). In embodiments, the first outer key pattern 135B may extend with a second width W2 in the range of about 2 μm to about 6 μm in the horizontal direction (X direction and Y direction). In embodiments, the first outer key pattern 136B may have an inner diameter R3 in the range of about 8 μm to about 24 μm in the horizontal direction (X direction and Y direction). In embodiments, the first outer key pattern 136B may have an outer diameter R4 in the range of about 12 μm to about 36 μm in the horizontal direction (X direction and Y direction). In embodiments, the first outer key pattern 136B may be spaced apart from a first inner key pattern 135B in the horizontal direction (X direction and Y direction) by a first distance D1 in the range of about 3 μm to about 9 μm by a first bonding dielectric layer 132B.

Referring to (B) of FIG. 4, the second key pattern group 134T may include the second inner key pattern 135T and the second outer key pattern 136T. The second outer key pattern 136T may surround the second inner key pattern 135T in the horizontal direction (X direction and Y direction). The second outer key pattern 136T may be spaced apart from the second inner key pattern 135T in the horizontal direction (X direction and Y direction) by the second bonding dielectric layer 132T. In embodiments, the second key pattern group 134T may have a size R10 in the range of about 14 μm to about 42 μm in the horizontal direction (X direction and Y direction). The second inner key pattern 135T may extend with the third width W3. The second outer key pattern 136T may extend with the fourth width W4. The third width W3 may be greater than the fourth width W4.

In embodiments, the second inner key pattern 135T may have a closed-loop shape of a ring on the plane (bonding surface 100TBS). In embodiments, the second inner key pattern 135T may extend with a third width W3 in the range of about 2 μm to about 6 μm in the horizontal direction (X direction and Y direction). In embodiments, the second inner key pattern 135T may have an inner diameter R6 in the range of about 2 μm to about 6 μm in the horizontal direction (X direction and Y direction). In embodiments, the second inner key pattern 135T may have an outer diameter R7 in the range of about 6 μm to about 18 μm in the horizontal direction (X direction and Y direction).

In embodiments, the second outer key pattern 136T may have a closed loop shape of a ring on a plane (bonding surface 100TBS). In embodiments, the second outer key pattern 136T may extend with a fourth width W4 in the range of about 1 μm to about 3 μm in the horizontal direction (X direction and Y direction). In embodiments, the second outer key pattern 136T may have an inner diameter R8 in the range of about 9 μm to about 27 μm in the horizontal direction (X direction and Y direction). In embodiments, the second outer key pattern 136T may have an outer diameter R9 in the range of about 11 μm to about 33 μm in the horizontal direction (X direction and Y direction). In embodiments, the second outer key pattern 136T may be spaced apart by a second distance D2 in the range of about 3 μm to about 9 μm from the second inner key pattern 135T in the horizontal direction (X direction and Y direction) by a second bonding dielectric layer 132T.

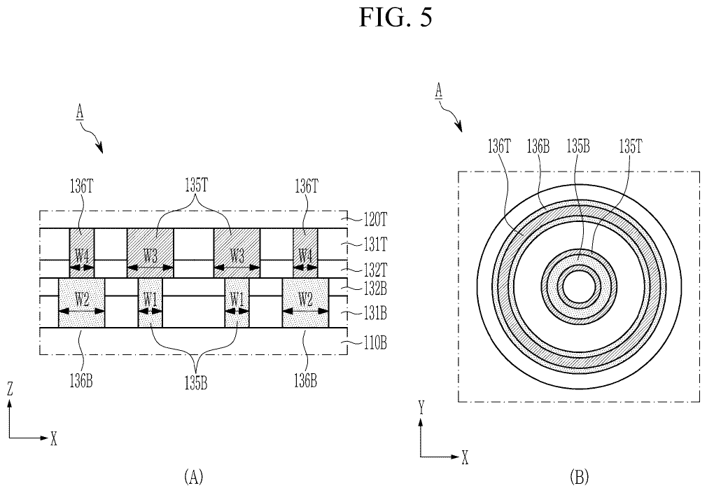

FIG. 5 is a cross-sectional view showing an enlarged view of region A of FIG. 1 and a plan view illustrating the first key pattern group 134B and the second key pattern group 134T overlapped with each other in region A.

Referring to (A) of FIG. 5, the first inner key pattern 135B of the first key pattern group 134B may be bonded to the second inner key pattern 135T of the second key pattern group 134T. The first inner key pattern 135B may extend with a first width W1. The second inner key pattern 135T may extend with a third width W3. The first width W1 may be smaller than the third width W3. The first outer key pattern 136B of the first key pattern group 134B may be bonded to the second outer key pattern 136T of the second key pattern group 134T. The first outer key pattern 136B may extend with a second width W2. The second outer key pattern 136T may extend with a fourth width W4. The second width W2 may be larger than the fourth width W4. In embodiments, the first width W1 may be the same as the fourth width W4. In embodiments, the second width W2 may be the same as the third width W3.

Referring to (B) of FIG. 5, the first inner key pattern 135B may be completely overlapped with the second inner key pattern 135T in a vertical direction (Z direction). The second outer key pattern 136T may be completely overlapped with the first outer key pattern 136B in a vertical direction (Z direction). The footprint of the first inner key pattern 135B may be included within the footprint of the second inner key pattern 135T. The footprint of the second outer key pattern 136T may be included within the footprint of the first outer key pattern 136B. An outline of the planar shape of the first inner key pattern 135B may extend conformally along the outline of the planar shape of the second inner key pattern 135T. The outline of the planar shape of the second outer key pattern 136T may extend conformally along the outline of the planar shape of the first outer key pattern 136B.

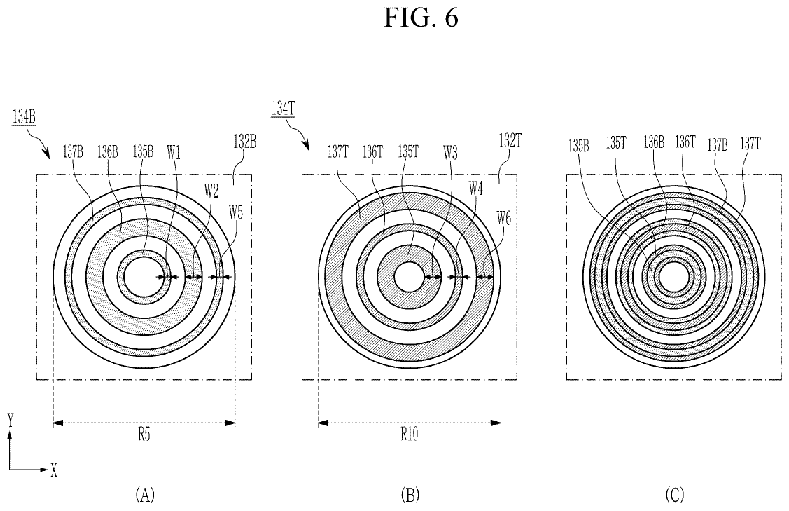

FIG. 6 is a plan view illustrating the first key pattern group 134B, the second key pattern group 134T, and the first key pattern group 134B and the second key pattern group 134T overlapped with each other, according to embodiments.

Referring to (A) of FIG. 6, the first key pattern group 134B may include a first key pattern 135B, a second key pattern 136B, and a fifth key pattern 137B. The second key pattern 136B may surround the first key pattern 135B in a horizontal direction (X direction and Y direction). The fifth key pattern 137B may surround the second key pattern 136B in a horizontal direction (X direction and Y direction). The first key pattern 135B, the second key pattern 136B, and the fifth key pattern 137B may be spaced apart from each other in a horizontal direction (X direction and Y direction) by the first bonding dielectric layer 132B. In embodiments, the first key pattern group 134B may have a size R5 in the range of about 14 μm to about 42 μm in a horizontal direction (X direction and Y direction). The first key pattern 135B may extend with a first width W1. The second key pattern 136B may extend with a second width W2. The fifth key pattern 137B may extend with a fifth width W5. The first width W1 may be less than the second width W2. The fifth width W5 may be less than the second width W2.

In embodiments, the first key pattern 135B, the second key pattern 136B, and the fifth key pattern 137B each may have a closed loop shape of a ring on a plane. In embodiments, the first key pattern 135B may extend with a first width W1 in the range of about 1 μm to about 3 μm in the horizontal direction (X direction and Y direction). In embodiments, the second key pattern 136B may extend with a second width W2 in the range of about 2 μm to about 6 μm in the horizontal direction (X direction and Y direction). In embodiments, the fifth key pattern 137B may extend with a fifth width W5 in the range of about 1 μm to about 3 μm in the horizontal direction (X direction and Y direction).

Referring to (B) of FIG. 6, second key pattern group 134T may include third key pattern 135T, fourth key pattern 136T, and sixth key pattern 137T. Fourth key pattern 136T may surround third key pattern 135T in the horizontal direction (X and Y directions). Sixth key pattern 137T may surround fourth key pattern 136T in the horizontal direction (X and Y directions). Third key pattern 135T, fourth key pattern 136T, and sixth key pattern 137T may be spaced apart from each other in the horizontal direction (X and Y directions) by second bonding dielectric layer 132T. In embodiments, second key pattern group 134T may have a size R10 in the range of about 14 μm to about 42 μm in the horizontal direction (X and Y directions). Third key pattern 135T may extend with third width W3. Fourth key pattern 136T may extend with fourth width W4. Sixth key pattern 137T may extend with sixth width W6. Third width W3 may be greater than fourth width W4. Sixth width W6 may be greater than fourth width W4.

In embodiments, the third key pattern 135T, the fourth key pattern 136T, and the sixth key pattern 137T may have a closed-loop shape of a ring on a plane. In embodiments, the third key pattern 135T may extend with a third width W3 in the range of about 2 μm to about 6 μm in the horizontal direction (X direction and Y direction). In embodiments, the fourth key pattern 136T may extend with a fourth width W4 in the range of about 1 μm to about 3 μm in the horizontal direction (X direction and Y direction). In embodiments, the sixth key pattern 137T may extend with a sixth width W6 in the range of about 2 μm to about 6 μm in the horizontal direction (X direction and Y direction).

Referring to FIG. 6(C), the first key pattern 135B may be completely overlapped with the third key pattern 135T in the vertical direction (Z direction). The fourth key pattern 136T may be completely overlapped with the second key pattern 136B in the vertical direction (Z direction). The fifth key pattern 137T may be completely overlapped with the sixth key pattern 137B in the vertical direction (Z direction). The footprint of the first key pattern 135B may be included within the footprint of the third key pattern 135T. The footprint of the fourth key pattern 136T may be included within the footprint of the second key pattern 136B. The footprint of the fifth key pattern 137B may be included within the footprint of the sixth key pattern 137T. The outline of the planar shape of the first key pattern 135B may extend conformally along the outline of the planar shape of the third key pattern 135T. The outline of the planar shape of the fourth key pattern 136T may extend conformally along the outline of the planar shape of the second key pattern 136B. The outline of the planar shape of the fifth key pattern 137B may extend conformally along the outline of the planar shape of the sixth key pattern 137T.

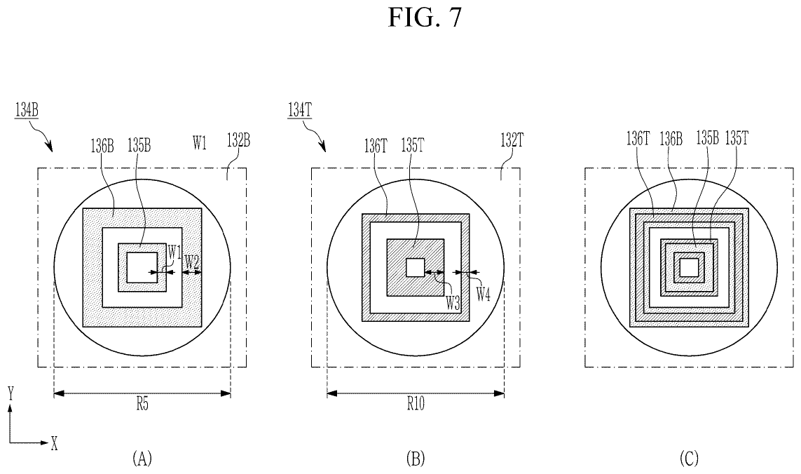

FIG. 7 is a plan view illustrating a first key pattern group 134B, a second key pattern group 134T, and the first key pattern group 134B and the second key pattern group 134T overlapped with each other, according to embodiments.

Referring to (A) of FIG. 7, the first key pattern group 134B may include a first inner key pattern 135B and a first outer key pattern 136B. The first outer key pattern 136B may surround the first inner key pattern 135B in a horizontal direction (X direction and Y direction). The first outer key pattern 136B may be spaced apart from the first inner key pattern 135B in a horizontal direction (X direction and Y direction) by the first bonding dielectric layer 132B. In embodiments, the first key pattern group 134B may have a size R5 in a range of about 14 μm to about 42 μm in a horizontal direction (X direction and Y direction). The first inner key pattern 135B may extend with a first width W1. The first outer key pattern 136B may extend with a second width W2. The first width W1 may be smaller than the second width W2.

In embodiments, the first inner key pattern 135B may have a closed-loop shape in a rectangular or a polygonal frame on the plane (bonding surface 100BBS). In embodiments, the first inner key pattern 135B may extend with a first width W1 in the range of about 1 μm to about 3 μm in the horizontal direction (X direction and Y direction). In embodiments, the first outer key pattern 136B may have a closed-loop shape in a rectangular or a polygonal frame on the plane (bonding surface 100BBS). In embodiments, the first outer key pattern 135B may extend with a second width W2 in the range of about 2 μm to about 6 μm in the horizontal direction (X direction and Y direction).

Referring to FIG. 7, section (B), the second key pattern group 134T may include a second inner key pattern 135T and a second outer key pattern 136T. The second outer key pattern 136T may surround the second inner key pattern 135T in the horizontal direction (X and Y directions). The second outer key pattern 136T may be spaced apart from the second inner key pattern 135T in the horizontal direction (X and Y directions) by the second bonding dielectric layer 132T. In embodiments, the second key pattern group 134T may have a size R10 in the range of about 14 μm to about 42 μm in the horizontal direction (X and Y directions). The second inner key pattern 135T may extend with a third width W3. The second outer key pattern 136T may extend with a fourth width W4. The third width W3 may be greater than the fourth width W4.

In embodiments, the second inner key pattern 135T may have a closed loop shape of a rectangular frame type or a polygonal frame type on the plane (bonding surface 100TBS). In embodiments, the second inner key pattern 135T may extend with a third width W3 in a range of about 2 μm to about 6 μm in the horizontal direction (X direction and Y direction). In embodiments, the second outer key pattern 136T may have a closed loop shape of a rectangular frame type or a polygonal frame type on the plane (bonding surface 100TBS). In embodiments, the second outer key pattern 136T may extend with a fourth width W4 in a range of about 1 μm to about 3 μm in the horizontal direction (X direction and Y direction).

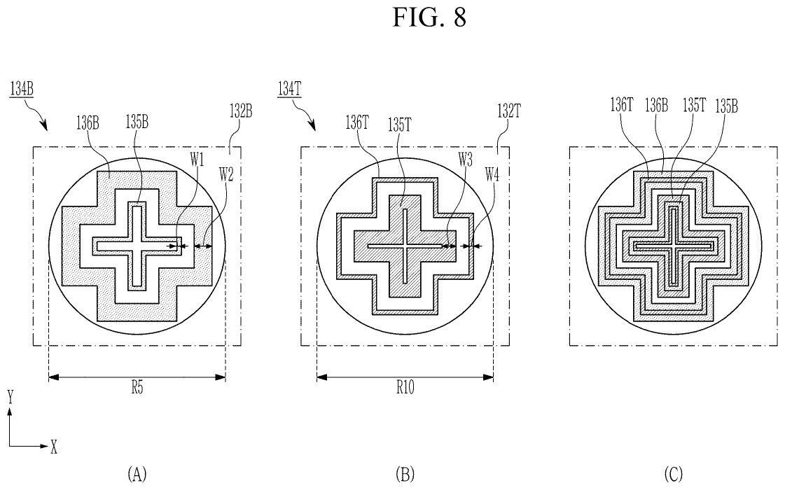

Referring to (C) of FIG. 7, the first inner key pattern 135B may be completely overlapped with the second inner key pattern 135T in the vertical direction (Z direction). The second outer key pattern 136T may be completely overlapped with the first outer key pattern 136B in the vertical direction (Z direction). The footprint of the first inner key pattern 135B may be included within the footprint of the second inner key pattern 135T. The footprint of the second outer key pattern 136T may be included within the footprint of the first outer key pattern 136B. The outline of the planar shape of the first inner key pattern 135B may extend conformally along the outline of the planar shape of the second inner key pattern 135T. The outline of the planar shape of the second outer key pattern 136T may extend conformally along the outline of the planar shape of the first outer key pattern 136B. FIG. 8 is a plan view showing the first key pattern group 134B, the second key pattern group 134T, and the first key pattern group 134B and the second key pattern group 134T overlapped with each other, according to embodiments.

Referring to (A) of FIG. 8, the first key pattern group 134B may include a first inner key pattern 135B and a first outer key pattern 136B. The first outer key pattern 136B may surround the first inner key pattern 135B in a horizontal direction (X direction and Y direction). The first outer key pattern 136B may be spaced apart from the first inner key pattern 135B in the horizontal direction (X direction and Y direction) by the first bonding dielectric layer 132B. In embodiments, the first key pattern group 134B may have a size R5 in a range of about 14 μm to about 42 μm in the horizontal direction (X direction and Y direction). The first inner key pattern 135B may extend with a first width W1. The first outer key pattern 136B may extend with a second width W2. The first width W1 may be smaller than the second width W2.

In embodiments, the first inner key pattern 135B may have a closed-loop shape of a cross-shaped on the plane (bonding surface 100BBS). In embodiments, the first inner key pattern 135B may extend with a first width W1 in the range of about 1 μm to about 3 μm in the horizontal direction (X direction and Y direction). In embodiments, the first outer key pattern 136B may have a closed-loop shape of a cross-shaped on the plane (bonding surface 100BBS). In embodiments, the first outer key pattern 135B may extend with a second width W2 in the range of about 2 μm to about 6 μm in the horizontal direction (X direction and Y direction).

Referring to (B) of FIG. 8, the second key pattern group 134T may include a second inner key pattern 135T and a second outer key pattern 136T. The second outer key pattern 136T may surround the second inner key pattern 135T in the horizontal direction (X direction and Y direction). The second outer key pattern 136T may be spaced apart from the second inner key pattern 135T in the horizontal direction (X direction and Y direction) by the second bonding dielectric layer 132T. In embodiments, the second key pattern group 134T may have a size R10 within a range of about 14 μm to about 42 μm in the horizontal direction (X direction and Y direction). The second inner key pattern 135T may extend with a third width W3. The second outer key pattern 136T may extend with a fourth width W4. The third width W3 may be greater than the fourth width W4.

In embodiments, the second inner key pattern 135T may have a closed-loop shape of a cross-shaped on a plane (bonding surface 100TBS). In embodiments, the second inner key pattern 135T may extend with a third width W3 in the range of about 2 μm to about 6 μm in the horizontal direction (X direction and Y direction). In embodiments, the second outer key pattern 136T may have a closed-loop shape of a cross-shaped on a plane (bonding surface 100TBS). In embodiments, the second outer key pattern 136T may extend with a fourth width W4 in the range of about 1 μm to about 3 μm in the horizontal direction (X direction and Y direction).

Referring to (C) of FIG. 8, the first inner key pattern 135B may be completely overlapped with the second inner key pattern 135T in the vertical direction (Z direction). The second outer key pattern 136T may be completely overlapped with the first outer key pattern 136B in the vertical direction (Z direction). The footprint of the first inner key pattern 135B may be included within the footprint of the second inner key pattern 135T. The footprint of the second outer key pattern 136T may be included within the footprint of the first outer key pattern 136B. The outline of the planar shape of the first inner key pattern 135B may extend conformally along the outline of the planar shape of the second inner key pattern 135T. The outline of the planar shape of the second outer key pattern 136T may extend conformally along the outline of the planar shape of the first outer key pattern 136B.

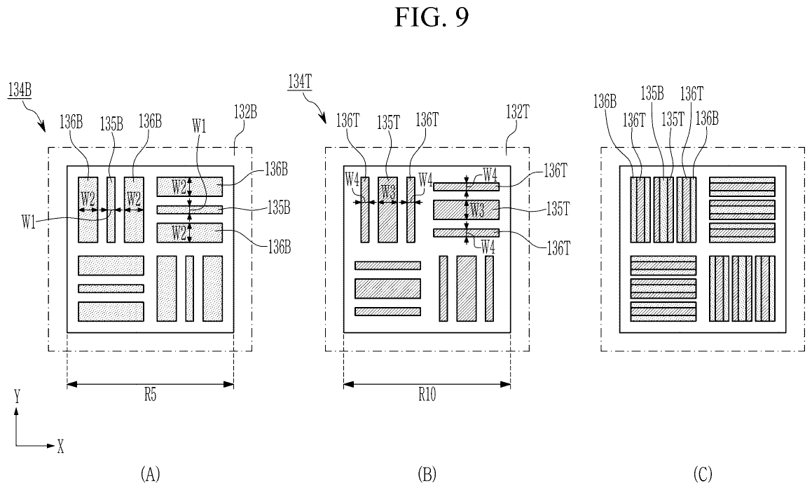

FIG. 9 is a plan view showing a first key pattern group 134B, a second key pattern group 134T, and the first key pattern group 134B and the second key pattern group 134T overlapped with each other according to embodiments.

Referring to (A) of FIG. 9, the first key pattern group 134B may include the first key pattern 135B and the second key pattern 136B. The first key pattern 135B and the second key pattern 136B may be arranged side by side in the first horizontal direction (X direction) or the second horizontal direction (Y direction). The first key pattern 135B and the second key pattern 136B may be arranged alternately with each other in the first horizontal direction (X direction) or the second horizontal direction (Y direction). The first key pattern 135B and the second key pattern 136B may be spaced apart with arbitrary intervals in the first horizontal direction (X direction) or the second horizontal direction (Y direction). In embodiments, the first key pattern group 134B may have a size R5 in the range of about 14 μm to about 42 μm in the horizontal direction (X direction and Y direction). The first key pattern 135B may extend with a first width W1. The second key pattern 136B may extend with a second width W2. The first width W1 may be smaller than the second width W2.

In embodiments, the first key pattern 135B may have an elongated or polygonal shape on a plane (bonding surface 100BBS). In embodiments, the first key pattern 135B may extend with a first width W1 in the range of about 1 μm to about 3 μm in the horizontal direction (X direction and Y direction). In embodiments, the second key pattern 136B may have an elongated or polygonal shape on a plane (bonding surface 100BBS). In embodiments, the first key pattern 135B may extend with a second width W2 in the range of about 2 μm to about 6 μm in the horizontal direction (X direction and Y direction).

Referring to (B) of FIG. 9, the second key pattern group 134T may include a third key pattern 135T and a fourth key pattern 136T. The third key pattern 135T and the fourth key pattern 136T may be arranged side by side in the first horizontal direction (X direction) or the second horizontal direction (Y direction). The third key pattern 135T and the fourth key pattern 136T may be arranged alternately in the first horizontal direction (X direction) or the second horizontal direction (Y direction). The third key pattern 135T and the fourth key pattern 136T may be spaced apart with arbitrary intervals in the first horizontal direction (X direction) or the second horizontal direction (Y direction). In embodiments, the second key pattern group 134T may have a size R10 in a range of about 14 μm to about 42 μm in the horizontal direction (X direction and Y direction). The third key pattern 135T may extend with a third width W3. The fourth key pattern 136T may extend with a fourth width W4. The third width W3 may be greater than the fourth width W4.

In embodiments, the third key pattern 135T may have an elongated or polygonal shape on the plane (bonding surface 100TBS). In embodiments, the third key pattern 135T may extend with a third width W3 in the range of about 2 μm to about 6 μm in the horizontal direction (X direction and Y direction). In embodiments, the fourth key pattern 136T may have an elongated or polygonal shape on the plane (bonding surface 100TBS). In embodiments, the fourth key pattern 136T may extend with a fourth width W4 in the range of about 1 μm to about 3 μm in the horizontal direction (X direction and Y direction).

Referring to (C) of FIG. 9, the first key pattern 135B may be completely overlapped with the third key pattern 135T in the vertical direction (Z direction). The fourth key pattern 136T may be completely overlapped with the second key pattern 136B in the vertical direction (Z direction). The footprint of the first key pattern 135B may be included within the footprint of the third key pattern 135T. The footprint of the fourth key pattern 136T may be included within the footprint of the second key pattern 136B. The outline of the planar shape of the first key pattern 135B may extend conformally along the outline of the planar shape of the third key pattern 135T. The outline of the planar shape of the fourth key pattern 136T may extend conformally along the outline of the planar shape of the second key pattern 136B.

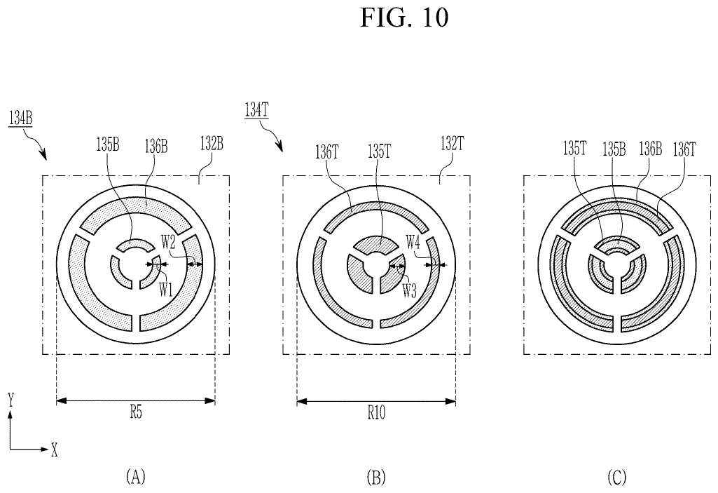

FIG. 10 is a plan view illustrating the first key pattern group 134B, the second key pattern group 134T, and the first key pattern group 134B and the second key pattern group 134T overlapped with each other in embodiments.

Referring to (A) of FIG. 10, the first key pattern group 134B may include the first inner key patterns 135B and the first outer key patterns 136B. The first outer key patterns 136B may surround the first inner key patterns 135B in a horizontal direction (X direction and Y direction). The first outer key patterns 136B may be spaced apart from the first inner key patterns 135B in the horizontal direction (X direction and Y direction) by a first bonding dielectric layer 132B. The first inner key patterns 135B may be spaced apart from each other. The first outer key patterns 136B may be spaced apart from each other. In embodiments, the first key pattern group 134B may have a size R5 in the range of about 14 μm to about 42 μm in the horizontal direction (X direction and Y direction). The first inner key patterns 135B may extend with a first width W1. The first outer key patterns 136B may extend with a second width W2. The first width W1 may be smaller than the second width W2.

In embodiments, each of the first inner key patterns 135B may have a circular arc shape on a plane (bonding surface 100BBS). In embodiments, each of the first inner key patterns 135B may extend in a horizontal direction (X direction and Y direction) with a first width W1 in the range of about 1 μm to about 3 μm. In embodiments, each of the first outer key patterns 136B may have a circular arc shape on a plane (bonding surface 100BBS). In embodiments, each of the first outer key patterns 136B may extend in a horizontal direction (X direction and Y direction) with a second width W2 in the range of about 2 μm to about 6 μm.

Referring to (B) of FIG. 10, the second key pattern group 134T may include second inner key patterns 135T and second outer key patterns 136T. The second outer key patterns 136T may surround the second inner key patterns 135T in the horizontal direction (X direction and Y direction). The second outer key patterns 136T may be spaced apart from the second inner key patterns 135T by a second bonding dielectric layer 132T in the horizontal direction (X direction and Y direction). The second inner key patterns 135T may be spaced apart from each other. The second outer key patterns 136T may be spaced apart from each other. In embodiments, the second key pattern group 134T may have a size R10 in the range of about 14 μm to about 42 μm in the horizontal direction (X direction and Y direction). The second inner key patterns 135T may extend with a third width W3. The second outer key patterns 136T may extend with a fourth width W4. The third width W3 may be greater than the fourth width W4.

In embodiments, each of the second inner key patterns 135T may have a circular arc shape on the plane (bonding surface 100TBS). In embodiments, each of the second inner key patterns 135T may extend with a third width W3 in the range of about 2 μm to about 6 μm in the horizontal direction (X direction and Y direction). In embodiments, each of the second outer key patterns 136T may have a circular arc shape on the plane (bonding surface 100TBS). In embodiments, each of the second outer key patterns 136T may extend with a fourth width W4 in the range of about 1 μm to about 3 μm in the horizontal direction (X direction and Y direction).

Referring to FIG. 10 (C), each of the first inner key patterns 135B may be completely overlapped with the corresponding second inner key pattern 135T of the second inner key patterns 135T in the vertical direction (Z direction). Each of the second outer key patterns 136T may be completely overlapped with the corresponding first outer key pattern 136B of the first outer key patterns 136B in the vertical direction (Z direction). The footprint of each of the first inner key patterns 135B may be included within the footprint of the corresponding second inner key pattern 135T of the second inner key patterns 135T. The footprint of each of the second outer key patterns 136T may be included within the footprint of the corresponding first outer key pattern 136B of the first outer key patterns 136B. The outline of the planar shape of each of the first inner key patterns 135B may conformally extend along the outline of the planar shape of the corresponding second inner key pattern 135T of the second inner key patterns 135T. The outline of the planar shape of each of the second outer key patterns 136T may conformally extend along the outline of the planar shape of the corresponding first outer key pattern 136B of the first outer key patterns 136B.

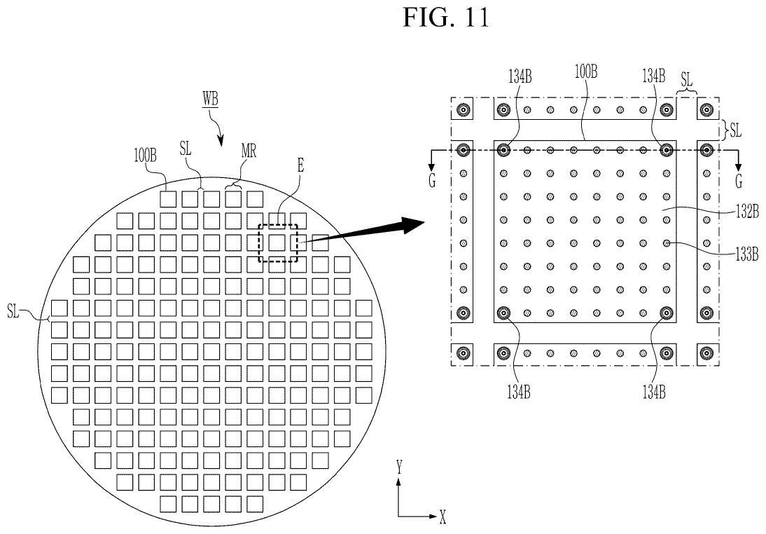

FIGS. 11 to 18 are cross-sectional views for explaining a method for manufacturing the semiconductor package 10 of embodiments of FIG. 1. The semiconductor package 10 may be manufactured by wafer-to-wafer bonding.

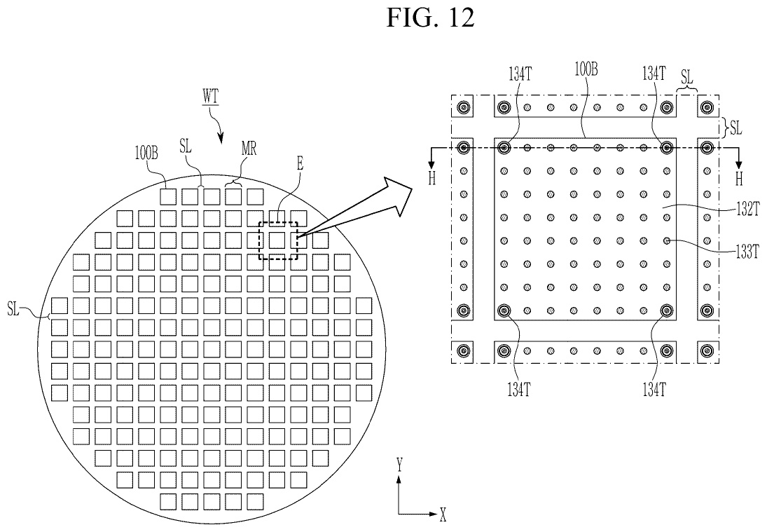

FIG. 11 is a plan view showing a first wafer WB having first semiconductor dies 100B formed thereon. FIG. 12 is a plan view showing a second wafer WT having second semiconductor dies 100T formed thereon.

Referring to FIG. 11 and FIG. 12, the first wafer WB may include main chip regions MR where a first semiconductor die 100B is formed in each main chip region MR, and scribe lanes SL partitioning the main chip regions MR. The second wafer WT may include main chip regions MR where a second semiconductor die 100T is formed in each main chip region MR, and scribe lanes SL partitioning the main chip regions MR. A hybrid bonding process may be applied to bond the first wafer WB and the second wafer WT, and to perform the hybrid bonding process, each of the first semiconductor dies 100B of the first wafer WB must be precisely aligned with the corresponding second semiconductor die 100T of the second wafer WT. Referring to region E of the first wafer WB and region E of the second wafer WT, to determine whether each of the first semiconductor dies 100B and the corresponding second semiconductor die 100T of the second semiconductor dies 100T are suitably aligned for hybrid bonding, the first semiconductor die 100B may include first key pattern groups 134B, and the second semiconductor die 100T may include second key pattern groups 134T. The first key pattern groups 134B are disposed at the corners of the first semiconductor die 100B, and the second key pattern groups 134T may be disposed at the corners of the second semiconductor die 100T.

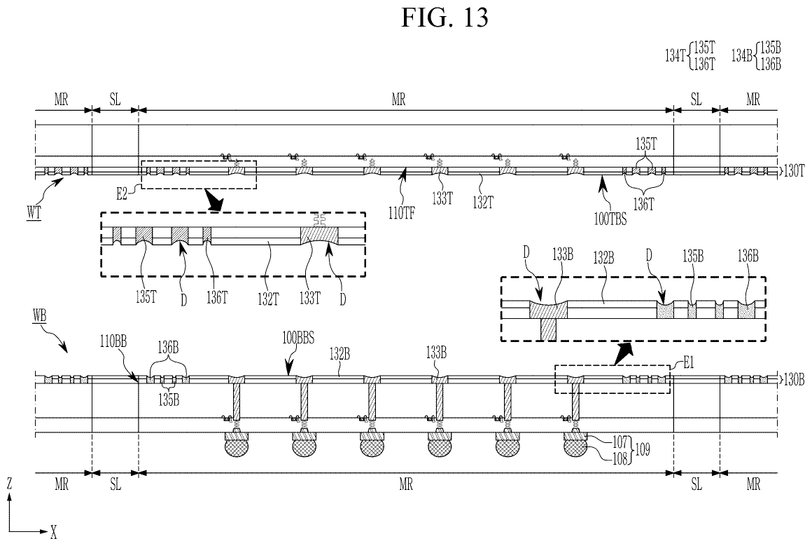

FIGS. 13 to 18 are cross-sectional views showing the region E of the first wafer WB in FIG. 11 cut along line G-G, and showing the region E of the second wafer WT in FIG. 12 cut along line H-H.

FIG. 13 is a cross-sectional view illustrating the step where the first wafer WB and the second wafer WT are aligned.

Referring to FIG. 13, a first wafer WB having a chemical mechanical polishing (CMP) process performed on the bonding surface 100BBS and a second wafer WT having a chemical mechanical polishing (CMP) process performed on the bonding surface 100TBS may be aligned.

Referring to the region E1 of the bonding surface 100TBS of the first wafer WB after performing a chemical mechanical polishing (CMP) process, due to the difference in the selectivity ratio of a film quality between the first bonding dielectric layer 132B and the first bonding pad 133B, and the influence of mechanical processing, dishing D that the central region of the first bonding pad 133B is removed more than the peripheral region of the first bonding pad 133B may form in the first bonding pad 133B in the first wafer WB. Additionally, due to the difference in the selectivity ratio of the film quality between the first bonding dielectric layer 132B and the first key pattern group 134B, and the influence of mechanical processing, dishing D may also form in the first inner key pattern 135B and the first outer key pattern 136B of the first key pattern group 134B.

Referring to the region E2 of the bonding surface 100TBS of the second wafer WT after performing a Chemical Mechanical Polishing (CMP) process, due to the difference in the selectivity ratio of a film quality of between the second bonding dielectric layer 132T and the second bonding pad 133T, and the influence of mechanical processing, dishing D that the central region of the second bonding pad 133T is removed more than the peripheral region of the second bonding pad 133T may be formed in the second bonding pads 133T of the second wafer WT. Additionally, due to due to the difference in the selectivity ratio of a film quality between the second bonding dielectric layer 132T and the second key pattern group 134T, and the influence of mechanical processing, dishing D may also be formed in the second inner key pattern 135T and the second outer key pattern 136T of the second key pattern group 134T.

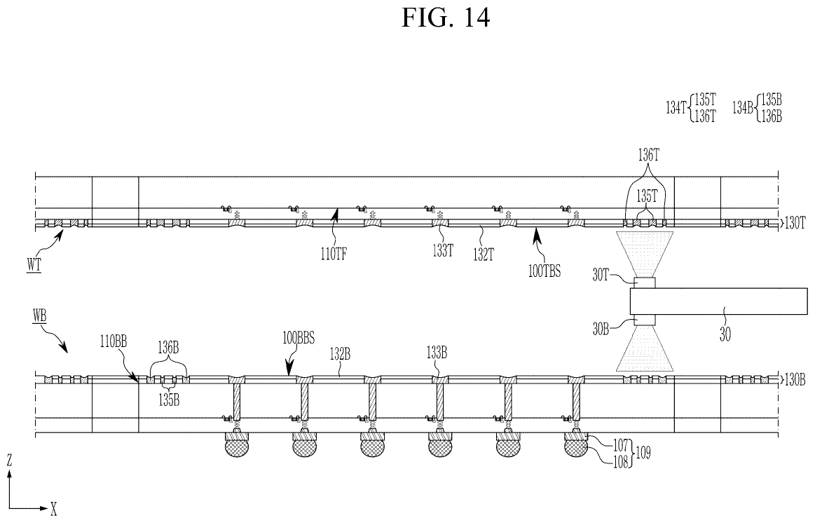

FIG. 14 is a cross-sectional view illustrating the step of measuring the alignment between the first key pattern group 134B of the first wafer WB and the second key pattern group 134T of the second wafer WT.

Referring to FIG. 14, an imaging device 30 may be located between a first wafer WB and a second wafer WT. The imaging device 30 may include a first camera 30B disposed to face the first wafer WB and a second camera 30T disposed to face the second wafer WT. The first camera 30B may photograph first key pattern groups 134B of the first wafer WB, and the second camera 30T may photograph second key pattern groups 134T of the second wafer WT. Each of the first key pattern groups 134B and a corresponding second key pattern group 134T of the second key pattern groups 134T may be photographed simultaneously or sequentially by the first camera 30B and the second camera 30T. After photographing is conducted, the alignment accuracy of each of the first semiconductor dies 100B of the first semiconductor dies 100B of the first wafer WB and a corresponding second semiconductor die 100T of the second semiconductor dies 100T of the second wafer WT may be measured by comparing a first image photographed for the first key pattern groups 134B and a second image photographed for the second key pattern groups 134T, based on determining whether a first inner key pattern 135B of the first key pattern groups 134B is aligned with a second inner key pattern 135T of the second key pattern groups 134T, and whether a first outer key pattern 136B of the first key pattern groups 134B is aligned with a second outer key pattern 136T of the second key pattern groups 134T.

When the alignment accuracy does not meet the reference value, based on the photographed result, at least one position of the first wafer WB and the second wafer WT may be adjusted, and the alignment accuracy between the first key pattern group 134B of the first wafer WB and the second key pattern group 134T of the second wafer WT may be re-measured.

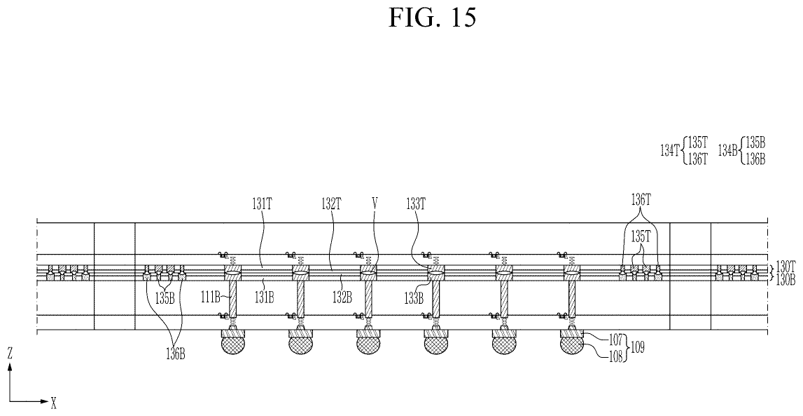

FIG. 15 is a cross-sectional view illustrating a step of bonding the first bonding dielectric layer 132B of the first wafer WB with the second bonding dielectric layer 132T of the second wafer WT.

Referring to FIG. 15, the first bonding dielectric layer 132B of the first wafer WB and the second bonding dielectric layer 132T of the second wafer WT may physically contact each other and be pre-bonded. The first bonding dielectric layer 132B of the first wafer WB and the second bonding dielectric layer 132T of the second wafer WT may be bonded to each other by covalent bonding. At this time, each of the first bonding pads 133B of the first wafer WB and the corresponding second bonding pad 133T of the second bonding pads 133T of the second wafer WT, each of the first inner key patterns 135B of the first wafer WB and the corresponding second inner key pattern 135T of the second inner key patterns 135T of the second wafer WT, and each of the first outer key patterns 136B of the first wafer WB and the corresponding second outer key pattern 136T of the second outer key patterns 136T of the second wafer WT are disposed in a state where they are not bonded to each other with a space V formed by the dishing D between them.

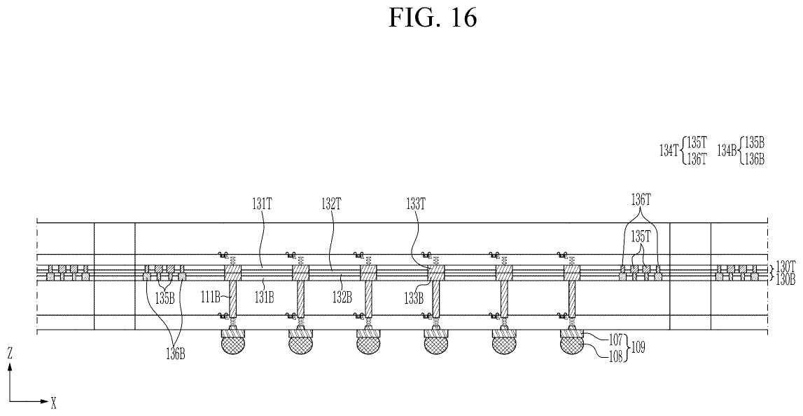

FIG. 16 is a cross-sectional view illustrating the step of performing annealing on a pre-bonded first wafer WB and a second wafer WT.

Referring to FIG. 16, an annealing process is performed, and each of the first bonding pads 133B of the first wafer WB may bond with the corresponding second bonding pad 133T of the second bonding pads 133T of the second wafer WT, each of the first inner key patterns 135B of the first wafer WB may bond with the corresponding second inner key pattern 135T of the second inner key patterns 135T of the second wafer WT, and each of the first outer key patterns 136B of the first wafer WB may bond with the corresponding second outer key pattern 136T of the second outer key patterns 136T of the second wafer WT. Due to the difference in the Coefficient of Thermal Expansion (CTE) between the dielectric, which is the material of the bonding dielectric layer, and the metal, which is the material of the bonding pads (or key pattern group), during the annealing process, each of the first bonding pads 133B of the first wafer WB and the corresponding second bonding pad 133T of the second bonding pads 133T of the second wafer WT and may expand to fill the space V formed by dishing D and are bonded to each other, each of the first inner key patterns 135B of the first wafer WB and the corresponding second inner key pattern 135T of the second inner key patterns 135T of the second wafer WT may expand to fill the space V formed by dishing D and are bonded to each other, and each of the first outer key patterns 136B of the first wafer WB and the corresponding second outer key pattern 136T of the second outer key patterns 136T of the second wafer WT may expand to fill the space V formed by dishing D and are bonded to each other. In embodiments, during the annealing process, the pressure may be less than about 30 MPa. In embodiments, the annealing process may be performed at a temperature of about 100° C. to about 500° C.

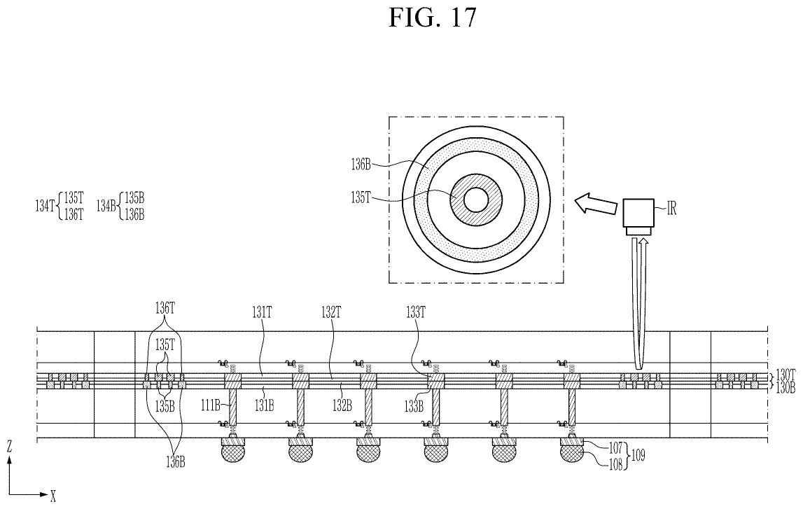

FIG. 17 is a cross-sectional view illustrating the step of measuring the bonding accuracy for the bonded first wafer WB and second wafer WT.

Referring to FIG. 17, the bonding accuracy of each of the first semiconductor dies 100B of the first semiconductor dies 100B of the first wafer WB with the corresponding second semiconductor dies 100T of the second semiconductor dies 100T of the second wafer WT may be measured using a detection device IR. The bonding accuracy of the first semiconductor die 100B and the second semiconductor die 100T may be performed by measuring the bonding accuracy between each of the first inner key pattern 135B of each of the first key pattern groups 134B and the second inner key pattern 135T of corresponding second key pattern group 134T of the second key pattern groups 134T, and between the first outer key pattern 136B of each of the first key pattern groups 134B and the second outer key pattern 136T a corresponding the second key pattern group 134T of the second key pattern groups 134T. In embodiments, the detection device IR may include an infrared detection device. The detection device IR may include an emitter and a detector. The emitter may direct light targeting the first key pattern group 134B and the second key pattern group 134T of the first semiconductor die 100B. The detector may detect light reflected from the first key pattern group 134B and the second key pattern group 134T. The detection device IR may generate a two-dimensional plane image from the light reflected from the first key pattern group 134B and the second key pattern group 134T. The image photographed by the detection device IR may include an overlapped image of the first inner key pattern 135B of each of the first inner key patterns 135B and the second inner key pattern 135T of each of the second inner key patterns 135T, and an overlapped image of the first outer key pattern 136B of each of the first outer key patterns 136B and the second outer key pattern 136T of each of the second outer key patterns 136T.

After this, the image may be analyzed to determine whether the bonding has been conducted accurately. When the first key pattern group 134B and the second key pattern group 134T are accurately bonded, the detection device IR may detect a two-dimensional plane image including only the second inner key pattern 135T of the second semiconductor dies 100T and the first outer key pattern 136B of the first semiconductor dies 100B since the first width W1 of the first inner key pattern 135B of the first key pattern group 134B is smaller than the third width W3 of the second inner key pattern 135T of the second key pattern group 134T, and the first inner key pattern 135B is completely overlapped with the second inner key pattern 135T in the vertical direction (Z direction), and the second width W2 of the first outer key pattern 136B of the first key pattern group 134B is greater than the fourth width W4 of the second outer key pattern 136T of the second key pattern group 134T, and the second outer key pattern 136T being completely overlapped with the first outer key pattern 136B in the vertical direction (Z direction). When the bonding accuracy of the first key pattern group 134B and the second key pattern group 134T is determined to be high, the bonding accuracy between each of the first bonding pads 133B of the first wafer WB and the corresponding second bonding pad 133T of second bonding pads 133T of the second wafer WT may also be considered high.

According to the present disclosure, without separately providing a bonding key pattern and an alignment key pattern, it may be measured whether the first semiconductor die 100B and the second semiconductor die 100T are accurately aligned before performing the hybrid process and whether the first semiconductor die 100B and the second semiconductor die 100T are accurately bonded after performing the hybrid process by a single key pattern group 134B and 134T that is bonded to each other. Thus, the area occupied by the key patterns on each semiconductor die may be reduced, and accordingly, the size of each semiconductor die may be decreased.

According to the disclosure, in addition to each first bonding pad 133B of the first bonding pads 133B of the first semiconductor die 100B being bonded to a corresponding second bonding pad 133T of the second bonding pads 133T of the second semiconductor die 100T by hybrid bonding, each of the first key pattern groups 134B of the first semiconductor die 100B is bonded to a corresponding second key pattern group 134T of the second key pattern groups 134T of the second semiconductor die 100T by hybrid bonding, thereby bonding quality between the semiconductor dies may be improved.

Also, according to the disclosure, by the position of each of the first key pattern groups 134B of the first semiconductor die 100B and the corresponding second key pattern group 134T of the second key pattern groups 134T of the second semiconductor die 100T, the metal ratio within the bonding layer of the first semiconductor die 100B and the bonding layer of the second semiconductor die 100T may be increased, and the interval between the key patterns within each bonding layer may be decreased. Thus, it may be possible to improve the topography of the bonding surface of each semiconductor die on which hybrid bonding is performed, and prevent the formation of voids on the bonding surface of each semiconductor die or the occurrence of delamination of the bonding surfaces during the process of performing hybrid bonding.

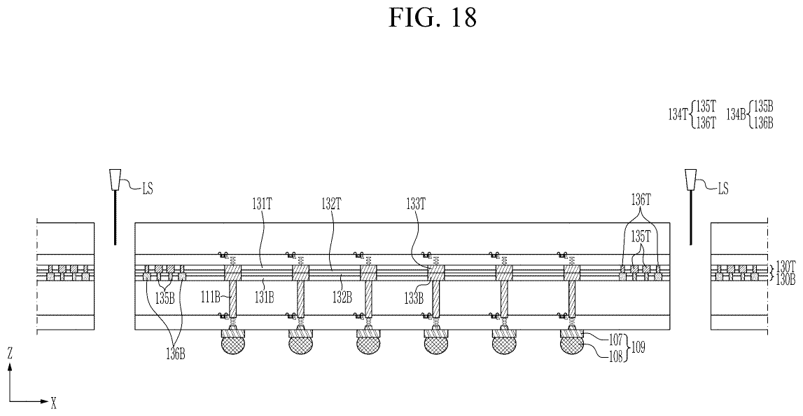

FIG. 18 is a cross-sectional view illustrating the step of singulating the bonded first wafer WB and second wafer WT into individual semiconductor packages 10.

Referring to FIG. 18, the bonded first wafer WB and the second wafer WT may be singulated into individual semiconductor packages 10 using the singulating equipment (LS). In embodiments, the singulating equipment (LS) may include a blade, laser, or plasma etching equipment.

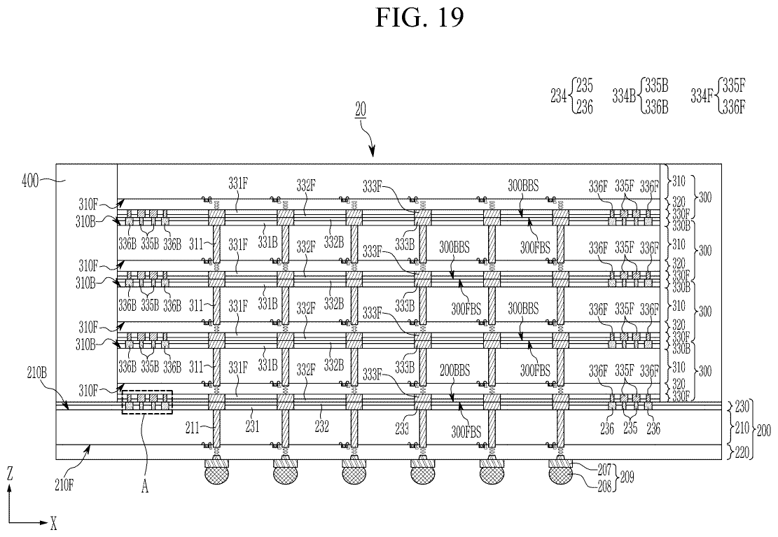

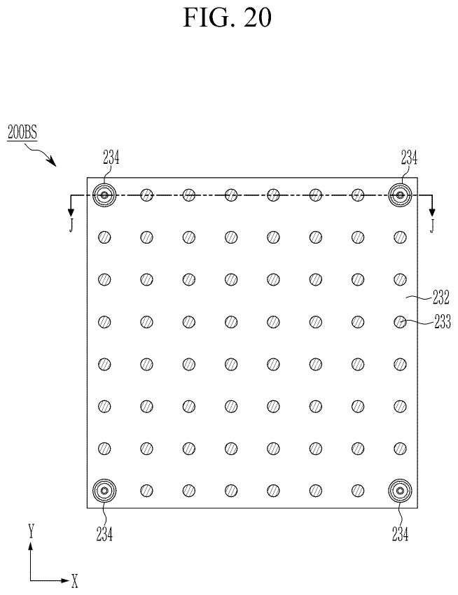

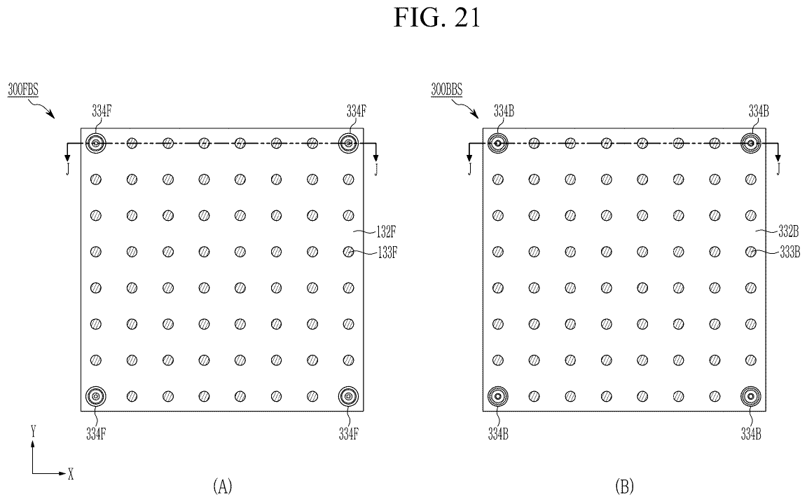

FIG. 19 is a cross-sectional view illustrating a semiconductor package 20 according to embodiments. FIG. 19 is a cross-sectional view showing the base die 200 of FIG. 20 and the semiconductor die 300 of FIG. 21, cut along line J-J.

Referring to FIG. 19, the semiconductor package 20 may include semiconductor dies (base die 200 and semiconductor dies 300), which are bonded by hybrid bonding and sequentially stacked from the bottom. The semiconductor package 20 may include bump structures 209, a base die (logic die; buffer die) 200, semiconductor dies 300, and molding material 400. The semiconductor package 20 may be a high bandwidth memory (HBM). High bandwidth memory (HBM) is a high-performance three-dimensional (3D) stacked dynamic random access memory (DRAM). High bandwidth memory (HBM) may implement shorter latency and higher bandwidth compared to conventional DRAM products through a semiconductor stack, which is manufactured by vertically stacking the semiconductor dies 300, and may decrease the total area occupied by the individual DRAMs on the substrate, providing an advantage in terms of high bandwidth relative to the area, and reducing power consumption.

Bump structures 209 may be located between the base die 200 and the external device. Each of the bump structures 209 is disposed on a corresponding wiring of wirings of the front side structure 220 of the base die 200 and may electrically connect the corresponding wiring of wirings of the front side structure 220 of the base die 200 to the external device. Each of the bump structures 209 may include a bump pillar 207 and a solder ball 208. In embodiments, the bump structures 209 may include micro bumps. The bump pillar 207 may be disposed between the corresponding wiring of wirings of the front side structure 220 of the base die 200 and the solder ball 208. In embodiments, the bump pillar 207 may be formed of copper alloy, including silver, chromium, nickel, tin, gold, and combinations thereof, or may be formed of copper. In embodiments, the solder ball 208 may include at least one of tin, silver, lead, nickel, copper, and their alloys.

The base die 200 may be disposed between the semiconductor dies 300 and the external device. The base die 200 may be a buffer die. When exchanging data between devices with differing data processing speeds, processing units, and usage times, data loss may occur due to differences in data processing speed, processing unit, and usage time between each device. To prevent such loss, by positioning the base die 200 between the semiconductor dies 300 and the external device, it may be possible to temporarily store information of the data exchange between the semiconductor dies 300 and the external device in the base die 200. When transmitting data to or receiving data from the semiconductor dies 300, the base die 200 may align the order of the data and then sequentially pass the data through.

The base die 200 may include a die base 210, a front side structure 220, first through silicon vias (TSV) 211, and a bonding layer 230. The die base 210 may include a front side 210F facing the bump structures 209 and a back side 210B opposite the front side 210F. The die base 210 may be a die formed from a wafer. In embodiments, the die base 210 may include silicon or another semiconductor material.

The front side structure 220 may be disposed between the die base 210 and the bump structures 209. The front side structure 220 may include a device layer and a wiring layer. The device layer may be disposed on the front side 210F of the die base 210. The device layer may include an integrated circuit structure having integrated circuit regions. In embodiments, the integrated circuit structure may include at least one of an active device and a passive device. In embodiments, the integrated circuit structure may include a gate structure, a source region, and a drain region. In embodiments, the integrated circuit structure may include at least one of a transistor, a diode, a capacitor, an inductor, and a resistor. The wiring layer may be disposed on the device layer. The wiring layer may include signal wiring lines, power wiring lines, contact plugs, and inter metal dielectric (IMD).

The first through silicon vias (TSV) 211 may extend from the wiring layer of the front side structure 220 through the die base 210 to the back side 210B of the die base 210. A first end of each of the first through silicon vias (TSV) 211 is connected to a corresponding bonding pad 233 of the bonding pads 233 of the bonding layer 230, and a second end of each of the first through silicon vias (TSV) 211 may be connected to the wiring line of the wiring layer of the front side structure 220. The second end may be the opposite end of the first end. In embodiments, the first through silicon vias (TSV) 211 may include at least one of tungsten, aluminum, copper, and alloys thereof. A barrier layer may be formed around each of the first through silicon vias (TSV) 211. The barrier layer may serve to prevent the silicon of the die base 210 or the dielectric of the front side structure 220 from contacting the first through silicon via (TSV) 211. In embodiments, the barrier layer may include at least one of titanium, tantalum, titanium nitride, tantalum nitride, and alloys thereof.

The bonding layer 230 may be disposed on the back side 210B of the die base 210. The bonding layer 230 may include a lower dielectric layer 231, a bonding dielectric layer (dielectric layer) 232, bonding pads 233, and key pattern groups 234.

The lower dielectric layer 231 may be disposed on the back side 210B of the die base 210. The lower dielectric layer 231 may be disposed between the die base 210 and the bonding dielectric layer 232. The lower dielectric layer 231 may surround bonding pads 233, and key pattern groups 234. In embodiments, the lower dielectric layer 231 may include silicon oxide, TEOS-formed oxide, or a combination thereof. In embodiments, the lower dielectric layer 231 may have a thickness in the range of about 0.1 μm to about 7 μm in the vertical direction (Z direction).

The bonding dielectric layer 232 may be disposed on the lower dielectric layer 231. The bonding dielectric layer 232 may be disposed between the lower dielectric layer 231 and the front side bonding dielectric layer 332F of the semiconductor die 300. The bonding dielectric layer 232 may perform dielectric-dielectric hybrid bonding and be bonded to the front side bonding dielectric layer 332F of the semiconductor die 300. The bonding dielectric layer 232 may surround the bonding pads 233 and key pattern groups 234. In embodiments, the bonding dielectric layer 232 may include a silicon compound. In embodiments, the bonding dielectric layer 232 may include silicon oxide or silicon nitride. In embodiments, the bonding dielectric layer 232 may include SiO₂, SiN, or SiCN. In embodiments, the bonding dielectric layer 232 may have a thickness in a vertical direction (Z direction) in the range of about 0.05 μm to about 1 μm.

The bonding pads 233 may penetrate the lower dielectric layer 231 and the bonding dielectric layer 232. Each of the bonding pads 233 may be disposed between the corresponding first through silicon via (TSV) 211 of the first through silicon vias (TSV) 211 and the corresponding front side bonding pad 332F of the front side bonding pads 332F of the semiconductor die 300. Each of the bonding pads 233 may electrically connect the corresponding first through silicon via (TSV) 211 of the first through silicon vias (TSV) 211 to the corresponding front side bonding pad 332F of the front side bonding pads 332F of the semiconductor die 300. Each of the bonding pads 233 may be bonded to the corresponding front side bonding pad 332F of the front side bonding pads 332F of the semiconductor die 300 by performing metal-metal hybrid bonding. By this metal-metal hybrid bonding, an electrical connection may be made between the base die 200 and the semiconductor die 300. The bonding surface of each of the bonding pads 233 may be coplanar with the bonding surface of the bonding dielectric layer 232. The sides of the bonding pads 233 may be surrounded by the lower dielectric layer 231 and the bonding dielectric layer 232. In embodiments, each of the bonding pads 233 may have a width in a range of about 0.01 μm to about 30 μm in a horizontal direction (X direction and Y direction). In embodiments, each of the bonding pads 233 may have a thickness in a range of about 0.1 μm to about 8 μm in a vertical direction (Z direction). In embodiments, the bonding pads 233 may include copper or a copper alloy.

The key pattern groups 234 may penetrate the lower dielectric layer 231 and the bonding dielectric layer 232. The key pattern groups 234 may be dummy patterns. The key pattern groups 234 may be electrically isolated from other configurations within the semiconductor package 20. Each of the key pattern groups 234 may include an inner key pattern (first key pattern) 235 and an outer key pattern (second key pattern) 236 around the inner key pattern 235. The key pattern groups 234 may include the same material as the bonding pads 233.

The inner key patterns 235 may penetrate the lower dielectric layer 231 and the bonding dielectric layer 232. The inner key patterns 235 may be a dummy pattern. The inner key patterns 235 may be electrically isolated from other configurations within the semiconductor package 20. Each of the inner key patterns 235 may be surrounded by a corresponding outer key pattern 236 of the outer key patterns 236 in a horizontal direction (X direction and Y direction; refer to FIG. 20). Each of the inner key patterns 235 may be spaced apart from a corresponding outer key pattern 236 of the outer key patterns 236 in a horizontal direction (X direction and Y direction; refer to FIG. 20). Each of the inner key patterns 235 may be bonded to a corresponding front side inner key pattern 335F of the front side inner key patterns 335F of an adjacent semiconductor die 300 by metal-metal hybrid bonding. The bonding surface of each of the inner key patterns 235 may be coplanar with the bonding surface of the bonding dielectric layer 232. The sides of each of the inner key patterns 235 may be surrounded by the lower dielectric layer 231 and the bonding dielectric layer 232. In embodiments, each of the inner key patterns 235 may have a thickness in the range of about 0.1 μm to about 8 μm in a vertical direction (Z direction). In embodiments, the inner key patterns 235 may include copper or a copper alloy.

The outer key patterns 236 may penetrate the lower dielectric layer 231 and the bonding dielectric layer 232. The outer key patterns 236 may be dummy patterns. The outer key patterns 236 may be electrically isolated from other configurations within the semiconductor package 20. Each of the outer key patterns 236 may surround a corresponding inner key pattern 235 of the inner key patterns 235 in the horizontal direction (X direction and Y direction; refer to FIG. 20). Each of the outer key patterns 236 may be spaced apart from a corresponding inner key pattern 235 of the inner key patterns 235 in the horizontal direction (X direction and Y direction; refer to FIG. 20). Each of the outer key patterns 236 may be bonded to a corresponding front side outer key pattern 336F of the front side outer key patterns 336F of an adjacent semiconductor die 300 by performing metal-metal hybrid bonding. Each bonding surface of the outer key patterns 236 may be coplanar with the bonding surface of the bonding dielectric layer 232. The sides of each of the outer key patterns 236 may be surrounded by the lower dielectric layer 231 and the bonding dielectric layer 232. In embodiments, each of the outer key patterns 236 may have a thickness in the range of about 0.1 μm to about 8 μm in the vertical direction (Z direction). In embodiments, the outer key patterns 236 may include copper or a copper alloy.

The semiconductor dies 300 may be disposed on the base die 200. The semiconductor dies 300 may configure a semiconductor stack, which is stacked sequentially in the vertical direction (Z direction) from the bottom. The sides of the semiconductor dies 300 may contact the molding material 400. In FIG. 1, a semiconductor stack including four semiconductor dies 300 is disclosed, but it is not limited thereto, and a semiconductor stack including a greater or lesser number of semiconductor dies 300 may be included within the scope of the present disclosure. For example, the semiconductor stack may include 4, 8, 12, 16, or 20 semiconductor dies 300.

The semiconductor die (memory die; core die) 300 may include a die base 310, a front side structure 320, second through silicon vias (TSV) 311, a back side bonding layer (first bonding layer; back side bonding structure) 330B, and a front side bonding layer (second bonding layer; front bonding structure) 330F. The semiconductor die 300 disposed at the topmost of the semiconductor stack may not include the second through silicon vias (TSV) 311 and the back side bonding layer 330B. In embodiments, the semiconductor die 300 may include DRAM.

The die base 310 may include a front side 310F facing the base die 200 and a back side 310B, which is the opposite side of the front side 310F. The die base 310 may be a die formed from a wafer. In embodiments, the die base 310 may include silicon or another semiconductor material.

The front side structure 320 may be disposed on the front side 310F of the die base 310. The front side structure 320 may include a device layer and a wiring layer. The device layer may be disposed on the front of the die base 310. The device layer may include an integrated circuit structure having integrated circuit regions. In embodiments, the integrated circuit structure may include at least one of an active device and a passive device. In embodiments, the integrated circuit structure may include a gate structure, a source region, and a drain region. In embodiments, the integrated circuit structure may include at least one of a transistor, a diode, a capacitor, an inductor, and a resistor. The wiring layer may be disposed on the device layer. The wiring layer may include signal wiring lines, power wiring lines, contact plugs, and an inter metal dielectric (IMD).

The second through silicon vias (TSV) 311 may extend from the wiring layer of the front side structure 320 through the die base 310 to the back side 310B of the die base 310. A first end of each of the second through silicon vias (TSV) 311 is connected to the corresponding back side bonding pad 333B of the back side bonding pads 333B of the back side bonding layer 330B, and a second end of each of the second through silicon vias (TSV) 311 may be connected to the wiring line of the wiring layer of the front side structure 320. The second end may be the opposite end of the first end. In embodiments, the second through silicon vias (TSV) 311 may include at least one of tungsten, aluminum, copper, and their alloys. A barrier layer may be formed around each of the second through silicon vias (TSV) 311. The barrier layer may function to prevent the silicon of the die base 310 or the dielectric of the front side structure 320 from contacting the second through silicon via (TSV) 311. In embodiments, the barrier layer may include at least one of titanium, tantalum, titanium nitride, tantalum nitride, and their alloys.

The back side bonding layer 330B may be disposed on the back side 310B of the die base 310. The back side bonding layer 330B may include a lower dielectric layer 331B, a back side bonding dielectric layer (first dielectric layer) 332B, back side bonding pads (first bonding pads) 333B, and back side key pattern groups (first key pattern groups) 334B.

The lower dielectric layer 331B may be disposed on the back side 310B of the die base 310. The lower dielectric layer 331B may be disposed between the die base 310 and the back side bonding dielectric layer 332B. The lower dielectric layer 331B may surround back side bonding pads 333B and back side key pattern groups 334B. In embodiments, the lower dielectric layer 331B may include silicon oxide, TEOS-formed oxide, or a combination thereof. In embodiments, the lower dielectric layer 331B may have a thickness in the vertical direction (Z direction) in the range of about 0.1 μm to about 7 μm.

The back side bonding dielectric layer 332B may be disposed on the lower dielectric layer 331B. The back side bonding dielectric layer 332B may be disposed between the lower dielectric layer 331B and the front side bonding dielectric layer 332F of an adjacent semiconductor die 300. The back side bonding dielectric layer 332B may perform dielectric-dielectric hybrid bonding and may be bonded to the front side bonding dielectric layer 332F of the adjacent semiconductor die 300. The back side bonding dielectric layer 332B may surround the back side bonding pads 333B, and the back side key pattern groups 334B. In embodiments, the back side bonding dielectric layer 332B may include a silicon compound. In embodiments, the back side bonding dielectric layer 332B may include silicon oxide or silicon nitride. In embodiments, the back side bonding dielectric layer 332B may include SiO₂, SiN, or SiCN. In embodiments, the back side bonding dielectric layer 332B may have a thickness in the range of about 0.05 μm to about 1 μm in the vertical direction (Z direction).

The back side bonding pads 333B may penetrate the lower dielectric layer 331B and the back side bonding dielectric layer 332B. Each of the back side bonding pads 333B may be disposed between a corresponding second through silicon via (TSV) 311 of the second through silicon vias (TSV) 311 and a corresponding front side bonding pad 333F of the front side bonding pads 333F of an adjacent semiconductor die 300. Each of the back side bonding pads 333B may electrically connect a corresponding second through silicon via (TSV) 311 of the second through silicon vias (TSV) 311 to a corresponding front side bonding pad 333F of the front side bonding pads 333F of an adjacent semiconductor die 300. Each of the back side bonding pads 333B may be bonded to a corresponding front side bonding pad 333F of the front side bonding pads 333F of an adjacent semiconductor die 300 by performing metal-metal hybrid bonding. Through this metal-metal hybrid bonding, an electrical connection may be formed between the semiconductor die 300 and the adjacent semiconductor die 300. The bonding surface of each of the back side bonding pads 333B may be coplanar with the bonding surface of the back side bonding dielectric layer 332B. The sides of the back side bonding pads 333B may be surrounded by the lower dielectric layer 331B and the back side bonding dielectric layer 332B. In embodiments, each of the back side bonding pads 333B may have a width in the range of about 0.01 μm to about 30 μm in the horizontal direction (X direction and Y direction). In embodiments, each of the back side bonding pads 333B may have a thickness in the range of about 0.1 μm to about 8 μm in the vertical direction (Z direction). In embodiments, the back side bonding pads 333B may include copper or a copper alloy.

The back side key pattern groups 334B may penetrate the lower dielectric layer 331B and the back side bonding dielectric layer 332B. The back side key pattern groups 334B may be a dummy pattern. The back side key pattern groups 334B may be electrically isolated from other configurations within the semiconductor package 20. Each of the back side key pattern groups 334B may include a back side inner key pattern (first key pattern) 335B and a back side outer key pattern (second key pattern) 336B surrounding the back side inner key pattern 335B. The back side key pattern groups 334B may include the same material as the back side bonding pads 333B.

The back side inner key patterns 335B may penetrate the lower dielectric layer 331B and the back side bonding dielectric layer 332B. The back side inner key patterns 335B may be dummy patterns. The back side inner key patterns 335B may be electrically isolated from other configurations within the semiconductor package 20. Each of the back side inner key patterns 335B may be surrounded by a corresponding back side outer key pattern 336B of the back side outer key patterns 336B in a horizontal direction (X direction and Y direction; refer to FIG. 20). Each of the back side inner key patterns 335B may be spaced apart from a corresponding back side outer key pattern 336B of the back side outer key patterns 336B in a horizontal direction (X direction and Y direction; refer to FIG. 20). Each of the back side inner key patterns 335B may be bonded to a corresponding front side inner key pattern 335F of the front side inner key patterns 335F of the front of an adjacent semiconductor die 300 by performing metal-metal hybrid bonding. The bonding surface of each of the back side inner key patterns 335B may be coplanar with the bonding surface of the back side bonding dielectric layer 332B. The sides of each of the back side inner key patterns 335B may be surrounded by the lower dielectric layer 331B and the back side bonding dielectric layer 332B. In embodiments, each of the back side inner key patterns 335B may have a thickness in the range of about 0.1 μm to about 8 μm in a vertical direction (Z direction). In embodiments, the back side inner key patterns 335B may include copper or a copper alloy.

The back side outer key patterns 336B may penetrate the lower dielectric layer 331B and the back side bonding dielectric layer 332B. The back side outer key patterns 336B may be dummy patterns. The back side outer key patterns 336B may be electrically isolated from other configurations within the semiconductor package 20. Each of the back side outer key patterns 336B may surround a corresponding back side inner key pattern 335B of the back side inner key patterns 335B in the horizontal direction (X direction and Y direction; refer to FIG. 20). Each of the back side outer key patterns 336B may be spaced apart from a corresponding back side inner key pattern 335B of the back side inner key patterns 335B in the horizontal direction (X direction and Y direction; refer to FIG. 20). Each of the back side outer key patterns 336B may be bonded to corresponding front side outer key patterns 336F of the front side outer key patterns 336F of the adjacent semiconductor die 300 by performing metal-metal hybrid bonding, the bonding surface of each of the back side outer key patterns 336B may be coplanar with the bonding surface of the back side bonding dielectric layer 332B. the sides of each of the back side outer key patterns 336B may be surrounded by the lower dielectric layer 331B and the back side bonding dielectric layer 332B. In embodiments, each of the back side outer key patterns 336B may have a thickness in the range of about 0.1 μm to about 8 μm in the vertical direction (Z direction). In embodiments, the back side outer key patterns 336B may include copper or a copper alloy.

The front side bonding layer (330F) may be disposed on the front side structure 320 of the die base 310. The front side bonding layer (330F) may include a lower dielectric layer 331F, a front side bonding dielectric layer (second dielectric layer) 332F, front side bonding pads (second bonding pads) 333F, and front side key pattern groups (second key pattern groups) 334F.

The lower dielectric layer 331F may be disposed on the front side structure 320 of the die base 310. The lower dielectric layer 331F may be disposed between the front side structure 320 of the die base 310 and the front side bonding dielectric layer 332F. The lower dielectric layer 331F may surround the front side bonding pads 333F and the front side key pattern groups 334F. In embodiments, the lower dielectric layer 331F may include silicon oxide, TEOS-formed oxide, or combinations thereof. In embodiments, the lower dielectric layer 331F may have a thickness in the range of about 0.1 μm to about 7 μm in the vertical direction (Z direction).

The front side bonding dielectric layer 332F may be disposed on the lower dielectric layer 331F. The front side bonding dielectric layer 332F may be disposed between the lower dielectric layer 331F and the back side bonding dielectric layer 332B of an adjacent semiconductor die 300. The front side bonding dielectric layer 332F of the semiconductor die 300 adjacent the base die 200 may be disposed between the lower dielectric layer 331F and the bonding dielectric layer 232 of the base die 200. The front side bonding dielectric layer 332F may be bonded to the back side bonding dielectric layer 332B of the adjacent semiconductor die 300 by dielectric-dielectric hybrid bonding. The front side bonding dielectric layer 332F of the semiconductor die 300 adjacent the base die 200 may be bonded to the bonding dielectric layer 232 of the base die 200 by dielectric-dielectric hybrid bonding. The front side bonding dielectric layer 332F may surround the front side bonding pads 333F and front side key pattern groups 334F. In embodiments, the front side bonding dielectric layer 332F may include a silicon compound. In embodiments, the front side bonding dielectric layer 332F may include silicon oxide or silicon nitride. In embodiments, the front side bonding dielectric layer 332F may include SiO₂, SiN, or SiCN. In embodiments, the front side bonding dielectric layer 332F may have a thickness in the range of about 0.05 μm to about 1 μm in the vertical direction (Z direction).

The front side bonding pads 333F may penetrate the lower dielectric layer 331F and the front side bonding dielectric layer 332F. Each of the front side bonding pads 333F may be disposed between the wiring line of the front side structure 320 and a corresponding back side bonding pad 333B of the back side bonding pads 333B of an adjacent semiconductor die 300. Each of the front side bonding pads 333F may electrically connect the wiring line of the front side structure 320 to a corresponding back side bonding pad 333B of the back side bonding pads 333B of an adjacent semiconductor die 300. Each of the front side bonding pads 333F of the semiconductor die 300 adjacent the base die 200 may be disposed between the wiring line of the front side structure 320 and a corresponding bonding pad 233 of the bonding pads 233 of the base die 200. Each of the front side bonding pads 333F of the semiconductor die 300 adjacent the base die 200 may electrically connect the wiring line of the front side structure 320 to a corresponding bonding pad 233 of the bonding pads 233 of the base die 200. Each of the front side bonding pads 333F may be bonded to a corresponding back side bonding pad 333B of the back side bonding pads 333B of an adjacent semiconductor die 300 by performing metal-metal hybrid bonding. Through this metal-metal hybrid bonding, an electrical connection may be formed between the semiconductor die 300 and the adjacent semiconductor die 300. Each of the front side bonding pads 333F of the semiconductor die 300 adjacent the base die 200 may be bonded to a corresponding bonding pad 233 of the bonding pads 233 of the base die 200 by performing metal-metal hybrid bonding. This metal-metal hybrid bonding may establish an electrical connection between the semiconductor die 300 and the base die 200. the bonding surface of each of the front side bonding pads 333F may be coplanar with the bonding surface of the front side bonding dielectric layer 332F. The sides of the front side bonding pads 333F may be surrounded by the lower dielectric layer 331F and the front side bonding dielectric layer 332F. In embodiments, each of the front side bonding pads 333F may have a width in the range of about 0.01 μm to about 30 μm in the horizontal direction (X direction and Y direction). In embodiments, each of the front side bonding pads 333F may have a thickness in the range of about 0.1 μm to about 8 μm in the vertical direction (Z direction). In embodiments, the front side bonding pads 333F may include copper or a copper alloy.

The front side key pattern groups 334F may penetrate the lower dielectric layer 331F and the front side bonding dielectric layer 332F. The front side key pattern groups 334F may be dummy patterns. The front side key pattern groups 334F may be electrically isolated from other configurations within the semiconductor package 20. Each of the front side key pattern groups 334F may include a front side inner key pattern (third key pattern) 335F and a front side outer key pattern (fourth key pattern) 336F surrounding the front side inner key pattern 335F. The front side key pattern groups 334F may include the same material as the front side bonding pads 333F.

The front side inner key patterns 335F may penetrate the lower dielectric layer 331F and the front side bonding dielectric layer 332F. The front side inner key patterns 335F may be dummy patterns. The front side inner key patterns 335F may be electrically isolated from other configurations within the semiconductor package 20. Each of the front side inner key patterns 335F may be surrounded by a corresponding front side outer key pattern 336F of the front side outer key patterns 336F in the horizontal direction (X direction and Y direction; refer to FIG. 20). Each of the front side inner key patterns 335F may be spaced apart from a corresponding front side outer key pattern 336F of the front side outer key patterns 336F in the horizontal direction (X direction and Y direction; refer to FIG. 20). Each of the front side inner key patterns 335F may be bonded to a corresponding back side inner key pattern 335B of the back side inner key patterns 335B of an adjacent semiconductor die 300 by performing metal-metal hybrid bonding. Each of the front side inner key patterns 335F of the semiconductor die 300 adjacent to the base die 200 may be bonded to a corresponding inner key pattern 235 of the inner key patterns 235 of the base die 200 by performing metal-to-metal hybrid bonding. The bonding surface of each of the front side inner key patterns 335F may be coplanar with the bonding surface of the front side bonding dielectric layer 332F. The sides of each of the front side inner key patterns 335F may be surrounded by the lower dielectric layer 331F and the front side bonding dielectric layer 332F. In embodiments, each of the front side inner key patterns 335F may have a thickness in the range of about 0.1 μm to about 8 μm in the vertical direction (Z direction). In embodiments, the front side inner key patterns 335F may include copper or a copper alloy.

The front side outer key patterns 336F may penetrate the lower dielectric layer 331F and the front side bonding dielectric layer 332F. The front side outer key patterns 336F may be a dummy pattern. The front side outer key patterns 336F may be electrically isolated from other configurations within the semiconductor package 20. Each of the front side outer key patterns 336F may surround a corresponding front side inner key pattern 335F of the front side inner key patterns 335F in the horizontal direction (X direction and Y direction; refer to FIG. 20). Each of the front side outer key patterns 336F may be spaced apart from a corresponding front side inner key pattern 335F of the front side inner key patterns 335F in the horizontal direction (X direction and Y direction; refer to FIG. 20). Each of the front side outer key patterns 336F may be bonded to a corresponding back side outer key pattern 336B of the back side outer key patterns 336B of the adjacent semiconductor die 300 through metal-metal hybrid bonding. Each of the front side outer key patterns 336F of the semiconductor die 300 adjacent to the base die 200 may be bonded to a corresponding outer key pattern 236 of the outer key patterns 236 of the base die 200 by performing metal-metal hybrid bonding, the bonding surface of each of the front side outer key patterns 336F may be coplanar with the bonding surface of the front side bonding dielectric layer 332F. The sides of each of the front side outer key patterns 336F may be surrounded by the lower dielectric layer 331F and the front side bonding dielectric layer 332F. In embodiments, each of the front side outer key patterns 336F may have a thickness in the range of about 0.1 μm to about 8 μm in the vertical direction (Z direction). In embodiments, the front side outer key patterns 336F may include copper or a copper alloy.

The molding material 400 may cover the semiconductor dies 300 on the base die 200. The top surface of the semiconductor die 300 disposed at the topmost may be exposed from the molding material 400, and may be coplanar with the top surface of the molding material 400.

FIG. 20 is a plan view illustrating the bonding surface 200BS of the base die 200 of FIG. 19.

Referring to FIG. 20, each of the key pattern groups 234 may be disposed on one corner of the die base 210 (or the bonding surface 200BS) of the base die 200. The key pattern groups 234 serve as a bonding key and alignment key together with the front side key pattern groups 334F of the adjacent semiconductor die 300, and the key pattern groups 234 may be disposed at an edge on the bonding surface 200BS of the base die 200 compared to the bonding pads 233.

FIG. 21 is a plan view showing the front side bonding surface 300FBS and the back side bonding surface 300BBS of the semiconductor die 300 of FIG. 19.

Referring to (A) of FIG. 21, each of the front side key pattern groups 334F may be disposed on one corner of the die base 310 (or front side bonding surface 300FBS) of the semiconductor die 300. The front side key pattern groups 334F may be disposed at an edge on the front side bonding surface 300FBS of the semiconductor die 300 in comparison with the front side bonding pads 333F. The front side key pattern groups 334F may serve as a bonding key and an alignment key.

Referring to (B) of FIG. 21, each of the back side key pattern groups 334B may be disposed on a corner of the die base 310 (or back side bonding surface 300BBS) of the semiconductor die 300. The back side key pattern groups 334B may be disposed at an edge on the back side bonding surface 300BBS of the semiconductor die 300 in comparison to the back side bonding pads 333B. The back side key pattern groups 334B may serve as a bonding key and an alignment key.

With reference to FIGS. 4 to 10, the content regarding the first key pattern group 134B and the second key pattern group 134T may be applied to the key pattern group 234, the back side key pattern group 334B, and the front side key pattern group 334F of the semiconductor package 20 in FIG. 19. Regarding bonding between the base die 200 and the semiconductor die 300, the content regarding the first key pattern group 134B described in FIGS. 4 to 10 may be applied to the key pattern group 234 of the base die 200, and the content regarding the second key pattern group 134T described in FIGS. 4 to 10 may be applied to the front side key pattern group 334F of the semiconductor die 300. Regarding bonding between the semiconductor dies 300, the content regarding the first key pattern group 134B described in FIGS. 4 to 10 may be applied to the back side key pattern group 334B of the semiconductor die 300 disposed at the bottom, and the content regarding the second key pattern group 134T described in FIGS. 4 to 10 may be applied to the front side key pattern group 334F of the semiconductor die 300 disposed at the top.

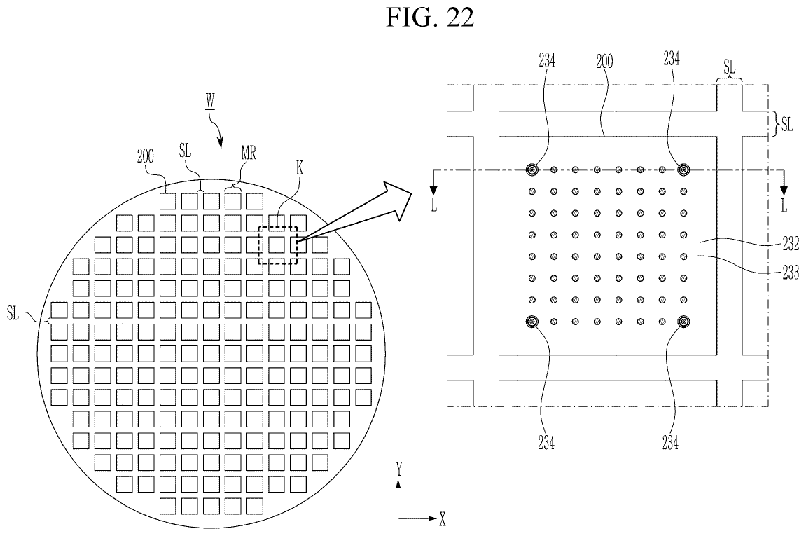

FIGS. 22 to 31 are cross-sectional views for describing a method for manufacturing a semiconductor package 20 of embodiments of FIG. 19. The semiconductor package 20 may be manufactured by a method of stacking semiconductor dies on a wafer.

FIG. 22 is a plan view illustrating a wafer W in which base dies 200 are formed.]

Referring to FIG. 22, the wafer W may include main chip regions MR where a base die 200 is formed in each of the main chip regions MR and a scribe lane SL partitioning the main chip regions MR. A hybrid bonding process of the wafer W to the semiconductor die 300 may be applied to bond the semiconductor die 300 onto the base die 200 of the wafer W, and to perform the hybrid bonding process, each of the base dies 200 of the wafer W must be precisely aligned with a corresponding semiconductor die 300 of semiconductor dies 300. Referring to region K of the wafer W, to determine whether each of the base dies 200 and the corresponding semiconductor die 300 of the semiconductor dies 300 are appropriately aligned for performing hybrid bonding, the base die 200 may include key pattern groups 234, and the semiconductor die 300 may include front side key pattern groups 334F (refer to FIG. 21). The key pattern groups 234 are disposed at the corners of the base die 200, and the front side key pattern groups 334F may be disposed at the corners of the semiconductor die 300.

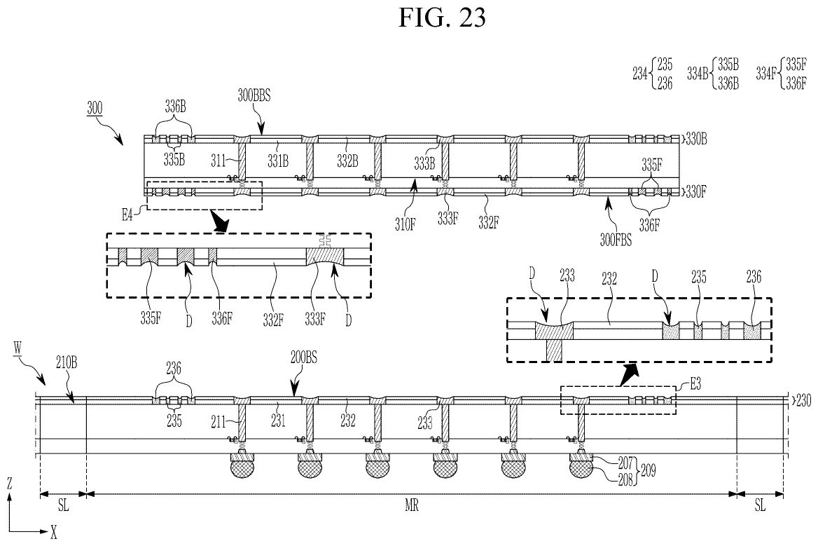

FIGS. 23 to 31 are cross-sectional views showing the semiconductor die 300 of FIG. 21 cut along line J-J, and the region K of the wafer W of FIG. 22 cut along line L-L.

FIG. 23 is a cross-sectional view illustrating the step of aligning the semiconductor die 300 on the wafer W.

Referring to FIG. 23, the wafer W on which a chemical mechanical polishing (CMP) process has been performed on the bonding surface 200BS and the semiconductor die 300 on which a CMP process has been performed on the bonding surface 300FBS may be aligned.

Referring to region E3 of the bonding surface 200BS of the wafer W where the chemical mechanical polishing (CMP) process has been performed, due to the difference in selectivity ratio between the film quality of the bonding dielectric layer 232 and the film quality of the bonding pad 233, and the effects of mechanical processing, dishing D that the central region of the bonding pad 233 is more significantly removed compared to the peripheral region of the bonding pad 233 may form in the bonding pads 233 of the wafer W. In addition, due to the difference in selectivity ratio between the film quality of the bonding dielectric layer 232 and the film quality of the key pattern group 234, as well as the effects of mechanical processing, dishing D may also form in the inner key pattern 235 and the outer key pattern 236 of the key pattern group 234.

Referring to region E4 of the bonding surface 300FBS of the semiconductor die 300 on which a chemical mechanical polishing (CMP) process has been performed, due to the difference in the selectivity ratio of the front side bonding dielectric layer 332F and the front side bonding pad 333F layers, as well as the impact of mechanical processing, dishing D may be formed on the front side bonding pads 333F of the semiconductor die 300, with the central region of the front side bonding pad 333F being removed more than the peripheral region of the front side bonding pad 333F. Additionally, due to the difference in the selectivity ratio of the front side bonding dielectric layer 332F and the front side key pattern group 334F layers, as well as the impact of mechanical processing, dishing D may also be formed on the front side inner key pattern 335F and the front side outer key pattern 336F of the front side key pattern group 334F.

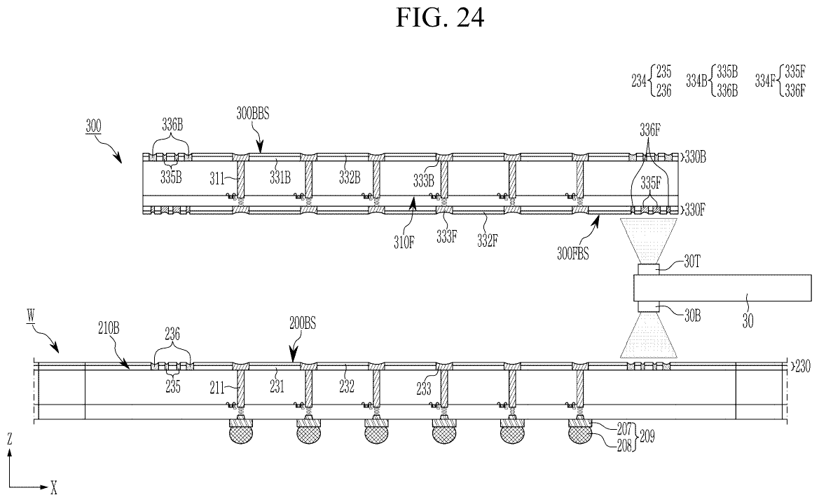

FIG. 24 is a cross-sectional view illustrating the step of measuring the alignment between the key pattern group 234 of the wafer W and the front side key pattern group 334F of the semiconductor die 300.

Referring to FIG. 24, an imaging device 30 may be positioned between the wafer W and the semiconductor die 300. The imaging device 30 may include a first camera 30B disposed to face the wafer W and a second camera 30T disposed to face the semiconductor die 300. The first camera 30B may photograph the key pattern groups 234 of the wafer W, and the second camera 30T may photograph the front side key pattern groups 334F of the semiconductor die 300. Each of the key pattern groups 234 and corresponding front side key pattern group 334F of the front side key pattern groups 334F may be photographed by the first camera 30B and the second camera 30T simultaneously or sequentially. After the photographing is performed, by comparing the first image photographed for the key pattern groups 234 and the second image photographed for the front side key pattern groups 334F, it is possible to measure the alignment accuracy of each of the base dies 200 of the wafer W with the semiconductor die 300 by determining whether the inner key pattern 235 of the key pattern group 234 is aligned with the front side inner key pattern 335F of the front side key pattern group 334F, and whether the outer key pattern 236 of the key pattern group 234 is aligned with the front side outer key pattern 336F of the front side key pattern group 334F.

If the alignment accuracy does not meet the reference value, the position of at least one of the wafer W and the semiconductor die 300 may be adjusted based on the photographed result. The alignment accuracy between the key pattern group 234 of the wafer W and the front side key pattern group 334F of the semiconductor die 300 may then be remeasured.

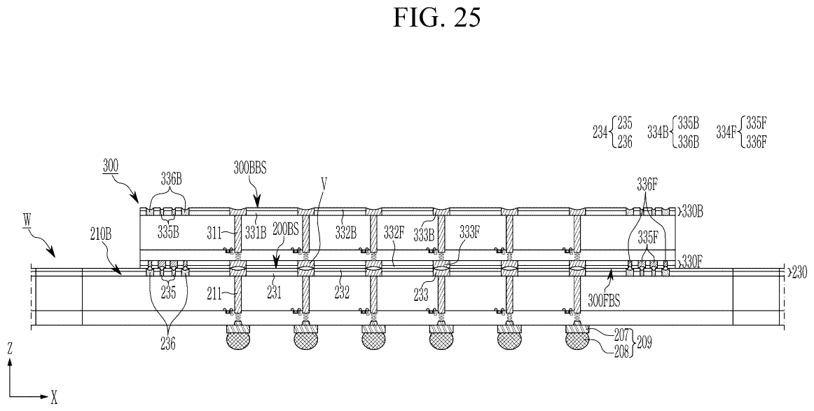

FIG. 25 is a cross-sectional view illustrating the step of bonding the bonding dielectric layer 232 of the wafer W to the front side bonding dielectric layer 332F of the semiconductor die 300.

Referring to FIG. 25, the bonding dielectric layer 232 of the wafer W and the front side bonding dielectric layer 332F of the semiconductor die 300 may physically contact and be pre-bonded. The bonding dielectric layer 232 of the wafer W and the front side bonding dielectric layer 332F of the semiconductor die 300 may be bonded to each other by covalent bonding. At this time, each bonding pad 233 of the bonding pads 233 of the wafer W and the corresponding front side bonding pad 333F of the front side bonding pads 333F of the semiconductor die 300, each inner key pattern 235 of the inner key patterns 235 of the wafer W and the corresponding front side inner key pattern 335F of the front side inner key patterns 335F of the semiconductor die 300, and each outer key pattern 236 of the outer key patterns 236 of the wafer W and the corresponding front side outer key pattern 336F of the front side outer key patterns 336F of the semiconductor die 300 are in a state of not being bonded to each other due to the space V formed by the dishing D between them.

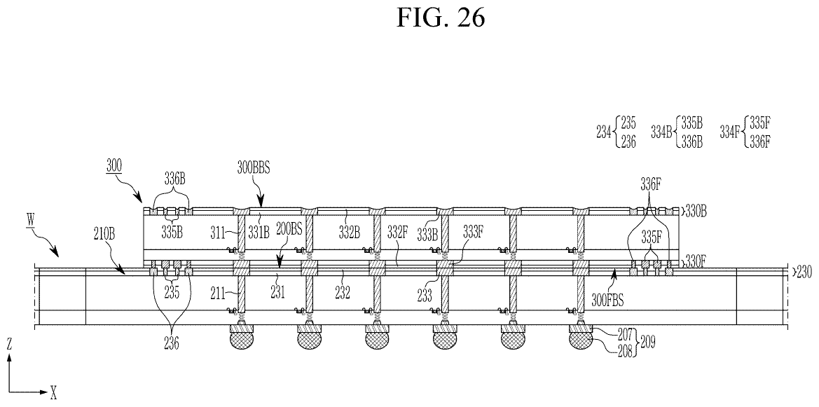

FIG. 26 is a cross-sectional view illustrating the step of performing annealing on the pre-bonded wafer W and the semiconductor die 300.

Referring to FIG. 26, an annealing process is conducted, and each bonding pad 233 of the bonding pads 233 of the wafer W and a corresponding front side bonding pad 333F of the front side bonding pads 333F of the semiconductor die 300, each inner key pattern 235 of the inner key patterns 235 of the wafer W and a corresponding front side inner key pattern 335F of the front side inner key patterns 335F of the semiconductor die 300, and each outer key pattern 236 of the outer key patterns 236 of the wafer W and a corresponding front side outer key pattern 336F of the front side outer key patterns 336F of the semiconductor die 300 may be bonded to each other. Due to the difference in the coefficient of thermal expansion (CTE) between the dielectric, which is the material of the bonding dielectric layer, and the metal, which is the material of the bonding pads (or key pattern group), during the annealing process, each bonding pad 233 of the bonding pads 233 of the wafer W and a corresponding front side bonding pad 333F of the front side bonding pads 333F of the semiconductor die 300, each inner key pattern 235 of the inner key patterns 235 of the wafer W and a corresponding front side inner key pattern 335F of the front side inner key patterns 335F of the semiconductor die 300, and each outer key pattern 236 of the outer key patterns 236 of the wafer W and a corresponding front side outer key pattern 336F of the front side outer key patterns 336F of the semiconductor die 300 may expand to fill the space V formed by dishing D and may be bonded to each other. In embodiments, the pressure during the annealing process may be less than about 30 MPa. In embodiments, the annealing process may be conducted at a temperature of about 100° C. to about 500° C.

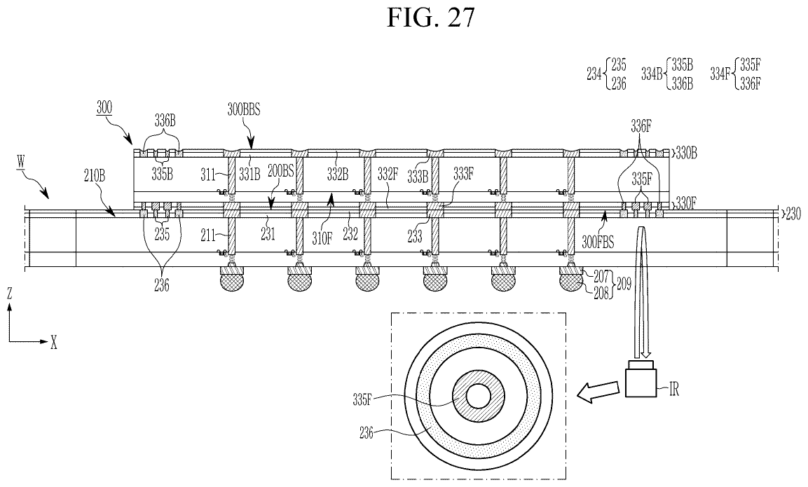

FIG. 27 is a cross-sectional view illustrating the step of measuring bonding accuracy for the wafer W and the semiconductor die 300 bonded with each other.

Referring to FIG. 27, the bonding accuracy between each base die 200 of base dies 200 of the wafer W and the semiconductor die 300 may be measured using a detection device IR. The bonding accuracy between the base die 200 and the semiconductor die 300 may be evaluated by measuring the bonding accuracy between inner key pattern 235 of each of the key pattern groups 234 and the front side inner key pattern 335F of a corresponding the front side key pattern group 334F of the front side key pattern groups 334F, and between outer key pattern 236 of the key pattern group 234 of the key pattern groups 234 and the front side outer key pattern 336F of a corresponding front side key pattern group 334F of the front side key pattern groups 334F. In embodiments, the detection device IR may include an infrared detection device. The detection device IR may include an emitter and a detector. The emitter may direct light targeting the key pattern group 234 of the base die 200 and the front side key pattern group 334F of the semiconductor die 300. The detector may detect light reflected from the key pattern group 234 of the base die 200 and the front side key pattern group 334F of the semiconductor die 300. The detection device IR may generate a two-dimensional plane image from the light reflected from the key pattern group 234 of the base die 200 and the front side key pattern group 334F of the semiconductor die 300. The image photographed by the detection device IR may include an overlay image of each inner key pattern 235 of the inner key patterns 235 and each front side inner key pattern 335F of the front side inner key patterns 335F, as well as an overlay image of each outer key pattern 236 of the outer key patterns 236 and each front side outer key pattern 336F of the front side outer key patterns 336F.

After this, the image may be analyzed to determine whether the bonding has performed accurately. When the key pattern group 234 of the base die 200 and the front side key pattern group 334F of the semiconductor die 300 are bonded accurately, the first width W1 of the inner key pattern 235 of the key pattern group 234 is smaller than the third width W3 of the front side inner key pattern 335F of the front side key pattern group 334F, the inner key pattern 235 completely overlaps with the front side inner key pattern 335F in the vertical direction (Z direction), the second width W2 of the outer key pattern 236 of the key pattern group 234 is larger than the fourth width W4 of the front side outer key pattern 336F of the front side key pattern group 334F, and the front side outer key pattern 336F completely overlaps with the outer key pattern 236 in the vertical direction (Z direction). As a result, the detection device IR may detect a two-dimensional plane image including only the front side inner key pattern 335F of the semiconductor die 300 and the outer key pattern 236 of the base die 200. If the bonding accuracy of the key pattern group 234 and the front side key pattern group 334F is determined to be high, the bonding accuracy between each bonding pad 233 of the bonding pads 233 of the base die 200 and the corresponding front side bonding pad 333F of the front side bonding pads 333F of the semiconductor die 300 may also be considered high.

According to the present disclosure, without separately providing a bonding key pattern and an alignment key pattern, it may be possible to measure whether the wafer W and the semiconductor die 300 are correctly aligned in the step before performing the hybrid process and whether the base die 200 and the semiconductor die 300 are correctly bonded in the step after performing the hybrid process by one key pattern group 234 and 324F that are bonded to each other. Thus, the area occupied by key patterns on each semiconductor die may be reduced, thereby allowing the size of each semiconductor die to be reduced.

According to the disclosure, in addition to each bonding pad 233 of the bonding pads 233 of the base die 200 being bonded to the corresponding front side bonding pad 333F of the front side bonding pads 333F of the semiconductor die 300 by hybrid bonding, each of the key pattern groups 234 of the base die 200 is bonded to the corresponding front side key pattern group 334F of the front side key pattern groups 334F of the semiconductor die 300 by hybrid bonding, thereby improving the bonding quality between the semiconductor dies.

Also, according to this disclosure, by the position of each of the key pattern groups 234 of base die 200 with the corresponding front side key pattern group 334F of the front side key pattern groups 334F of semiconductor die 300, the metal ratio within the bonding layer of base die 200 and semiconductor die 300 may be increased, and the interval between key patterns within the bonding layer may be reduced. This way, the topography of the bonding surface of each semiconductor die on which hybrid bonding is performed may be improved, and during the process of performing hybrid bonding, voids forming on the bonding surface of each semiconductor die, or delamination between bonding surfaces, may be prevented.

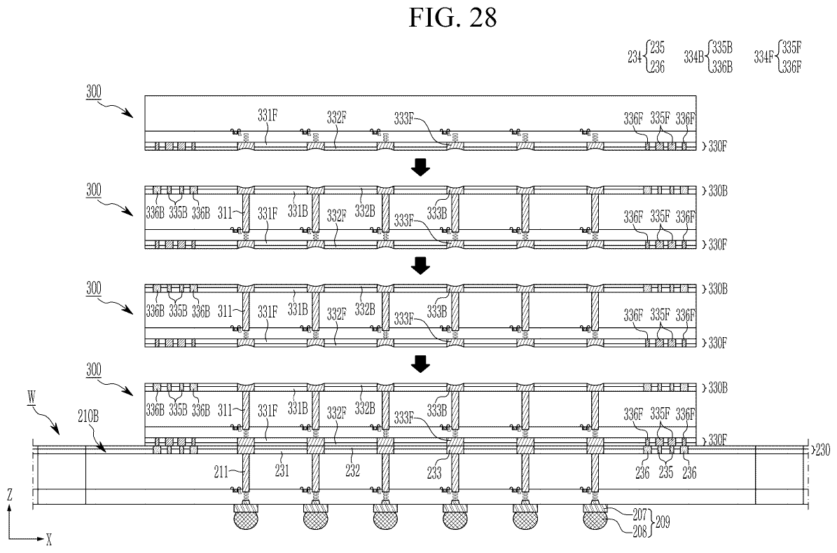

FIG. 28 is a cross-sectional view illustrating the step of sequentially stacking semiconductor dies 300.

Referring to FIG. 28, semiconductor dies 300 may be sequentially stacked on a semiconductor die 300 already bonded to the wafer W. In each step where the semiconductor die 300 is stacked on a semiconductor die 300 already bonded to the wafer W through hybrid bonding, the steps described in FIGS. 23 to 27 may be repeated.

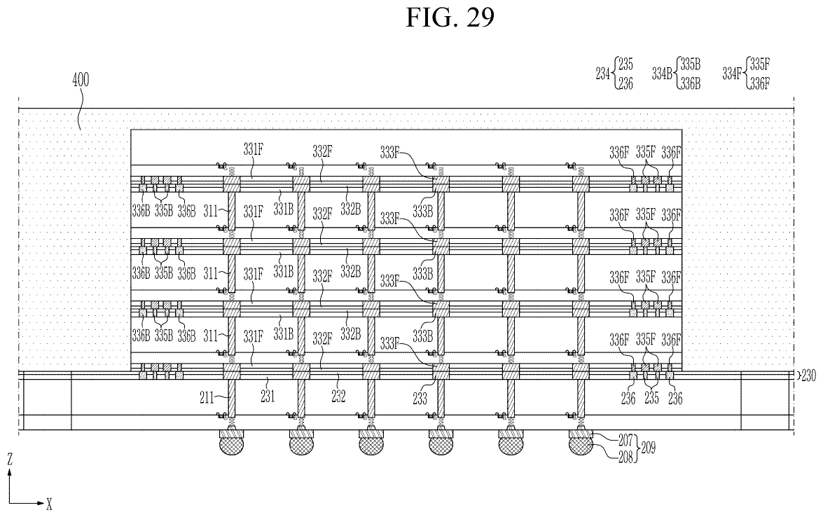

FIG. 29 is a cross-sectional view illustrating the step of molding semiconductor dies 300 on a wafer W.

Referring to FIG. 29, the semiconductor dies 300 may be covered with the molding material 400 on the wafer W. In embodiments, the process of molding with the molding material 400 may include a compression molding process or a transfer molding process. In embodiments, the molding material 400 may include an epoxy molding compound (EMC).

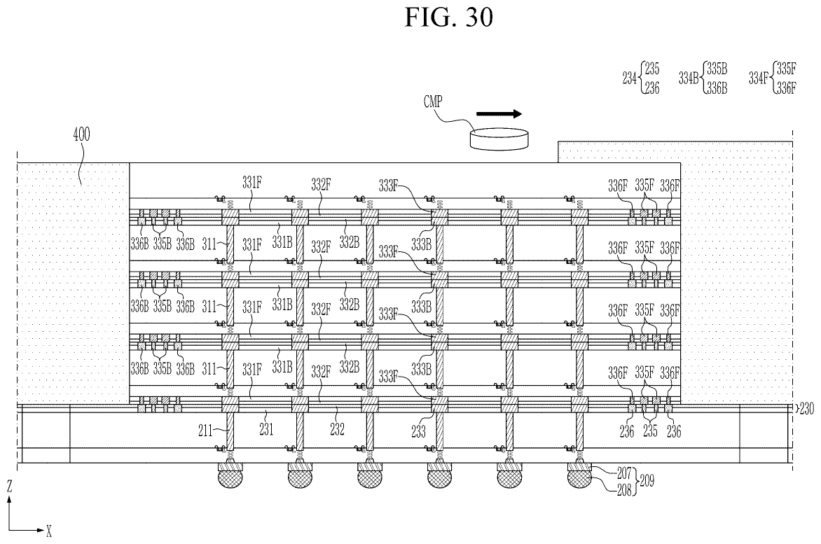

FIG. 30 is a cross-sectional view illustrating the step of performing a chemical mechanical polishing (CMP) process on the molding material 400.

Referring to FIG. 30, a chemical mechanical polishing (CMP) process may be performed to planarize the upper surface of the molding material 400. After performing the chemical mechanical polishing (CMP) process, the upper surface of the semiconductor die 300 disposed at the top may be exposed.

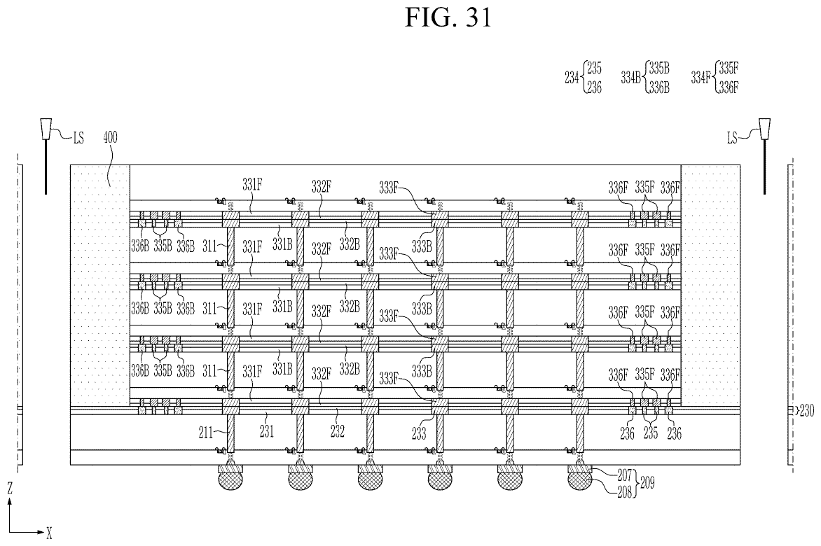

FIG. 31 is a cross-sectional view illustrating the step of singulating a reconstructed wafer W including semiconductor packages 20 into individual semiconductor packages 20.

Referring to FIG. 31, the reconstituted wafer W, including semiconductor packages 20, may be singulated into individual semiconductor packages 20 using a singulating equipment (LS). In embodiments, the singulating equipment (LS) may utilize a blade, laser, or plasma etching equipment.

Although the preferred embodiments of the present disclosure have been described above, the present disclosure is not limited thereto, and various modifications may be made within the scope of the claims, the detailed description of the invention, and the attached drawings, which should also fall within the scope of the present disclosure.

What is claimed is:

1. A semiconductor package comprising:
a first semiconductor die and a second semiconductor die on the first semiconductor die,
the first semiconductor die comprising:
a first die base;
a first bonding dielectric layer on a back side of the first die base;
a plurality of first key patterns penetrating the first bonding dielectric layer; and
a plurality of second key patterns penetrating the first bonding dielectric layer, each second key pattern surrounding a corresponding first key pattern of the plurality of first key patterns,
the second semiconductor die comprising:
a second die base;
a second bonding dielectric layer disposed on a front side of the second die base and bonded to the first bonding dielectric layer;
a plurality of third key patterns penetrating the second bonding dielectric layer, each third key pattern bonding to a corresponding first key pattern of the plurality of first key patterns; and
a plurality of fourth key patterns penetrating the second bonding dielectric layer, each fourth key pattern surrounding a corresponding third key pattern of the plurality of third key patterns and bonding to a corresponding second key pattern of the plurality of second key patterns,
wherein:
each of the plurality of first key patterns has a first width in a horizontal direction,
each of the plurality of second key patterns has a second width in the horizontal direction,
each of the plurality of third key patterns has a third width in the horizontal direction,
each of the plurality of fourth key patterns has a fourth width in the horizontal direction,
the first width is smaller than the third width, and
the second width is larger than the fourth width.

2. The semiconductor package of claim 1, wherein the plurality of first key patterns and the plurality of third key patterns each in a plane include:
a closed-loop shape of a ring, a polygonal frame, or a cross-shaped;
an elongated shape; or
a circular arc shape.

3. The semiconductor package of claim 1, wherein the plurality of second key patterns and the plurality of fourth key patterns each in a plane include:
a closed loop shape of a ring, a polygonal frame, or a cross-shaped;
an elongated shape; or
a circular arc shape.

4. The semiconductor package of claim 1, wherein the first width is smaller than the second width, and the third width is greater than the fourth width.

5. The semiconductor package of claim 1, wherein the first width is equal to the fourth width, and the second width is equal to the third width.

6. The semiconductor package of claim 1, wherein each of the plurality of first key patterns is completely overlapped in the vertical direction with a corresponding third key pattern of the plurality of third key patterns.

7. The semiconductor package of claim 1, wherein each of the plurality of fourth key patterns is completely overlapped in the vertical direction with the corresponding second key pattern of the plurality of second key patterns.

8. The semiconductor package of claim 1, wherein an outline of the planar shape of each of the plurality of first key patterns extends conformally along an outline of the planar shape of a corresponding third key pattern of the plurality of third key patterns.

9. The semiconductor package of claim 1, wherein an outline of planar shape of each of the plurality of fourth key patterns extends conformally along an outline of the planar shape of the corresponding second key pattern of the plurality of second key patterns.

10. The semiconductor package of claim 1, wherein:
the first semiconductor die further includes a plurality of fifth key patterns penetrating the first bonding dielectric layer,
each of the plurality of fifth key patterns surrounds a corresponding second key pattern of the plurality of second key patterns,
the second semiconductor die further includes a plurality of sixth key patterns penetrating the second bonding dielectric layer,
each sixth key pattern of the plurality of sixth key patterns surrounds a corresponding fourth key pattern of the plurality of fourth key patterns, and bonded to the corresponding fifth key pattern of the plurality of fifth key patterns,
each of the plurality of fifth key patterns has a fifth width in the horizontal direction,
each of the plurality of sixth key patterns has a sixth width in the horizontal direction, and
the fifth width is smaller than the sixth width.

11. The semiconductor package of claim 10, wherein the fifth width is smaller than the second width, and the sixth width is larger than the fourth width.

12. A semiconductor package comprising:
a first semiconductor die comprising a first die base and a first bonding layer on a back side of the first die base; and
a second semiconductor die comprising a second die base and a second bonding layer on a front side of the second die base,
wherein the first bonding layer includes:
a first dielectric layer;
a plurality of first bonding pads penetrating the first dielectric layer; and
a plurality of first key pattern groups penetrating the first dielectric layer,
wherein each of the plurality of first key pattern groups includes a first inner key pattern and a first outer key pattern around the first inner key pattern, and
the second bonding layer includes:
a second dielectric layer bonded to the first dielectric layer;
a plurality of second bonding pads penetrating the second dielectric layer, wherein each of the plurality of second bonding pads is bonded to a corresponding first bonding pad of the plurality of first bonding pads; and
a plurality of second key pattern groups penetrating the second dielectric layer,
wherein each of the plurality of second key pattern groups includes a second inner key pattern and a second outer key pattern around the second inner key pattern, and the second inner key pattern is bonded to the corresponding first inner key pattern, and the second outer key pattern is bonded to the corresponding first outer key pattern, and
wherein a width in a horizontal direction of the first inner key pattern is smaller than a width in the horizontal direction of the second inner key pattern, and a width in the horizontal direction of the first outer key pattern is larger than a width in the horizontal direction of the second outer key pattern.

13. The semiconductor package of claim 12, wherein the plurality of first key pattern groups and the plurality of second key pattern groups are dummy patterns.

14. The semiconductor package of claim 12, wherein the plurality of first bonding pads and the plurality of second bonding pads include copper or a copper alloy.

15. The semiconductor package of claim 12, wherein the first dielectric layer and the second dielectric layer include SiO₂, SiN, or SiCN.

16. The semiconductor package of claim 12, wherein the plurality of first key pattern groups and the plurality of second key pattern groups include copper or a copper alloy.

17. The semiconductor package of claim 12, wherein the plurality of first key pattern groups and the plurality of second key pattern groups include a same material as a material of the plurality of first bonding pads and the plurality of second bonding pads.

18. A semiconductor package comprising:
a semiconductor stack in which a plurality of semiconductor dies are sequentially stacked from the bottom,
wherein each of the plurality of semiconductor dies comprises:
a die base including a front side and a back side opposite the front side;
a device layer on the front side;
a wiring layer on the device layer; and
at least one of a front side bonding layer on the wiring layer and a back side bonding layer on the back side,
wherein each of the front side bonding layer and the back side bonding layer includes a dielectric layer and a plurality of key pattern groups penetrating the dielectric layer, and
wherein each of the plurality of key pattern groups includes an inner key pattern and an outer key pattern surrounding the inner key pattern,
wherein:
the dielectric layer of back side bonding layer of each of the plurality of semiconductor dies is bonded to the dielectric layer of the front side bonding layer of an adjacent semiconductor die,
the inner key pattern of back side bonding layer of each of the plurality of semiconductor dies is bonded to the inner key pattern of the front side bonding layer of an adjacent semiconductor die,
the outer key pattern of back side bonding layer of each of the plurality of semiconductor dies is bonded to the outer key pattern of the front side bonding layer of an adjacent semiconductor die,
the inner key pattern of back side bonding layer of each of the plurality of semiconductor dies has a first width in a horizontal direction,
the outer key pattern of back side bonding layer of each of the plurality of semiconductor dies has a second width in the horizontal direction,
the inner key pattern of front side bonding layer of each of the plurality of semiconductor dies has a third width in the horizontal direction,
the outer key pattern of front side bonding layer of each of the plurality of semiconductor dies has a fourth width in the horizontal direction,
the first width is less than the third width, and
the second width is greater than the fourth width.

19. The semiconductor package of claim 18, wherein the inner key pattern of each of the plurality of key pattern groups is spaced apart from the corresponding outer key pattern.

20. The semiconductor package of claim 18, wherein each of the plurality of key pattern groups is disposed on one corner of the die base.
